(19) United States
(12) Patent Application Publication
(10) Pub. No.: US 2015/0145014 A1
(43) Pub. Date: May 28, 2015

(54) VERTICAL MEMORY DEVICES

(71) Applicants: Su-Jin SHIN, Hwaseong-si (KR); Dong-Chul YOO, Seongnam-si (KR); Ki-Hyun HWANG, Seongnam-si (KR)

(72) Inventors: Su-Jin SHIN, Hwaseong-si (KR); Dong-Chul YOO, Seongnam-si (KR); Ki-Hyun HWANG, Seongnam-si (KR)

(21) Appl. No.: 14/471,778

(22) Filed: Aug. 28, 2014

(30) Foreign Application Priority Data
Nov. 27, 2013 (KR) 10-2013-0145552

(51) Int. Cl. H01L 27/115; H01L 29/792; H01L 29/51; H01L 29/788

(52) U.S. Cl. CPC H01L 27/11563; H01L 29/7889; H01L 29/7926; H01L 27/11517; H01L 29/511; H01L 29/518
USPC 257/314

(57) ABSTRACT

A vertical memory device includes a substrate, a first cell block and a second cell block. The substrate includes a central region and a peripheral region. At least one first cell block is on the central region. The first cell block includes a first channel and first gate lines. At least one second cell block is on the peripheral region. The second cell block includes a second channel and second gate lines. The second cell block has a width greater than a width of the first cell block. The first and second channel extend in a first direction vertical to a top surface of the substrate. The first gate lines surround the first channel and the first gate lines are spaced apart from each other in the first direction. The second gate lines surround the second channel and are spaced apart from each other in the first direction.

### CROSS-REFERENCE TO RELATED APPLICATION

This application claims priority under 35 USC §119 to Korean Patent Application No. 10-2013-0145552, filed on Nov. 27, 2013 in the Korean Intellectual Property Office (KIPO), the contents of which are incorporated by reference herein in their entirety.

### BACKGROUND

1. Field

Example embodiments relate to vertical memory devices and/or methods of manufacturing the same. More particularly, example embodiments relate to non-volatile memory devices including vertical channels and/or methods of manufacturing the same.

2. Description of Related Art

Recently, a vertical memory device including memory cells stacked vertically with respect to a top surface of a substrate has been developed in order to realize a high degree of integration. In the vertical memory device, a channel may vertically protrude from the top surface of the substrate, and gate lines and insulation layers surrounding the channel may be vertically stacked.

As an integration degree of the vertical memory device becomes greater, the stacked number of the insulation layers and the gate lines may be increased to cause mechanical and/or physical stress.

### SUMMARY

Example embodiments relate to a vertical memory device having high integration and excellent reliability.

Example embodiments relate to a method of manufacturing a vertical memory device having high integration and excellent reliability.

According to example embodiments, there is a vertical memory device. The vertical memory device includes a substrate, at least one first cell block and at least one second cell block. The substrate includes a central region and a peripheral region. The at least one first cell block is on the central region. The first cell block includes a first channel extending in a first direction to a top surface of the substrate and first gate lines surrounding the first channel and spaced apart from each other in the first direction. The at least one second cell block is on the peripheral region. The second cell block has a width that is greater than a width of the first cell block. The second cell blocks includes a second channel extending in the first direction vertical to the top surface of the substrate, and second gate lines surrounding the second channel and spaced apart from each other in the first direction.

In example embodiments, the first cell block may include a plurality of first channels, the plurality of first channels may form a first channel bundle, the second cell block may include a plurality of second channels, and the plurality of second channels may form a second channel bundle.

In example embodiments, a number of the second channel bundles included in the second cell block may be greater than a number of the first channel bundles included in the first cell block.

In example embodiments, the first cell block may include one first channel bundle, and the second cell block may include at least two second channel bundles.

In example embodiments, the second cell block may further include a separation layer pattern between two of the at least two channel bundles that neighbor each other.

In example embodiments, the first gate lines of the first cell block may include a first ground selection line (GSL), at least one first word line, and a first string selection line (SSL) sequentially stacked on each other from the top surface of the substrate. The second gate lines of the second cell block may include a second ground selection line (GSL), at least one second word line, and a second string selection line (SSL) sequentially stacked on each other from the top surface of the substrate The separation layer pattern may extend through the second SSL of the second cell block.

In example embodiments, the at least one first cell block may be a plurality of first cell blocks on the central region, and the at least one second cell block may be one second cell block on the peripheral region.

In example embodiments, the second cell block may further include a supporting pattern at a central portion of the second gate lines at each level of the second gate lines spaced apart from each other in the first direction.

In example embodiments, the first cell block may further include first insulating interlayer patterns stacked on each other between the first gate lines in the first direction, the second cell block may further include second insulating interlayer patterns stacked on each other between the second gate lines in the first direction. The first and second insulating interlayer patterns may include silicon dioxide. The supporting pattern may include silicon nitride.

In example embodiments, the vertical memory device may further include filling layer patterns on the substrate. The at least one first cell block may be a plurality of first cell blocks on the centrally region. The at least one second cell block may be one or a plurality of second cell blocks on the peripheral region. The filling layer pattern may extend between at least one of the plurality of first cell blocks and the plurality of second cell blocks.

In example embodiments, the at least one second cell block may be the plurality of second cell blocks, and the filling layer patterns may extend between the plurality of first cell blocks and the plurality of second cell blocks. A distance between the filling layer patterns on the peripheral region that neighbor each other may be greater than a distance between the filling layer patterns on the central region that neighbor each other.

In example embodiments, the first cell block and the second cell block may be spaced apart from each other in a second direction, the first and second gate lines may extend in a third direction, the filling layer patterns may extend in the third direction, the second direction and third direction may be parallel to the top surface of the substrate, and the second direction and third direction may be perpendicular to each other.

In example embodiments, the peripheral region may be a dummy region.

In example embodiments, the vertical memory device may further include a bit line selectively and electrically connected to the first channel of the first cell block.

According to example embodiments, there is provided a vertical memory device. The vertical memory device includes a substrate, a plurality of first cell blocks, and a plurality of second cell blocks. The substrate includes a central region and a peripheral region. The plurality of first cell blocks are on the central region. The first cell block includes a first channel extending in a first direction vertical to a top surface of the substrate, and first gate lines surrounding the first channel and spaced apart from each other in the first direction. The plurality of second cell blocks are on the peripheral region. The second cell block includes a second channel extending in the first direction vertical to the top surface of the substrate and second gate lines surrounding the second channel and spaced apart from each other in the first direction. A distance between the plurality of second cell blocks that neighbor each other is greater than a distance between the plurality of first cell blocks that neighbor each other.

In example embodiments, the plurality of first cell blocks and the plurality of second cell blocks may have a same width.

According to example embodiments, a method of manufacturing a vertical memory device includes forming a mold structure by forming a mold structure by forming insulating interlayers and sacrificial layers alternately and repeatedly on a substrate, the substrate including a central region and a peripheral region to form a mold structure; forming channels in the mold structure, the channels extending through the mold structure in a first direction vertical to a top surface of the substrate; forming at least at least one first cell block and at least one second cell block on the central region and the peripheral region, respectively, of the substrate by partially etching the mold structure, the second cell block has a width greater than a width of the first cell block; removing the sacrificial layers from the first cell block and the second cell block; and forming gate lines are at spaces where the sacrificial layers were removed. The gate lines include first gate lines in the first cell block and second gate lines in the second cell block.

In example embodiments, the method further may further include forming openings by partially etching the mold structure. The first cell block and the second cell block may be defined by the openings.

In example embodiments, a distance between the openings on the peripheral region that neighbor each other may be greater than a distance between the openings on the central region that neighbor each other.

In example embodiments, a plurality of the channels may define a channel bundle. A number of the channel bundles in the second cell block may be greater than a number of the channel bundles in the first cell block.

In example embodiments, a ratio of the distance between the neighboring openings on the peripheral region and the distance between the neighboring openings on the central region may be greater than or equal to two.

In example embodiments, a separation layer pattern may be formed through an upper portion of the mold structure included in the second cell block. The separation layer pattern may extend between the channel bundles of the second cell block that neighbor each other.

In example embodiments, the forming openings may include exposing sidewalls of the sacrificial layers. The removing the sacrificial layers may include a wet etching process.

In example embodiments, the removing the sacrificial layers may include partially removing the sacrificial layers in the second cell block. Remaining portions of the sacrificial layers in the second cell block, after the partially removing the sacrificial layers, may define supporting patterns in the second cell block.

In example embodiments, the insulating interlayer may include silicon oxide, and the sacrificial layer may include using silicon nitride.

According to example embodiments, a vertical memory device includes a substrate and a stacked structure on the substrate. The substrate includes a central region and a peripheral region. The stacked structure includes a plurality of channels extending a first direction through a plurality of gate lines and a plurality of insulating layers alternately stacked on each other on the substrate. The plurality of channels are spaced apart from each other. The plurality of gate lines and the plurality of insulating layers define openings that expose the substrate and separate the stacked structure into a plurality of first cell blocks on the central region and at least one second cell block on the peripheral region of the substrate. Each one of the at least one second cell block has one of a width that is different than a width of any one of the plurality of first cell blocks, and a different separation distance from an adjacent one of the plurality of first cell blocks compared to a separation distance between the plurality of first cell blocks that neighbor each other.

In example embodiments, each one of the at least one second cell block may have the width that is different than the width of any one of the plurality of first cell blocks. The width of each one of the at least one second cell block may be greater than the width of any one of the plurality of first cell blocks. A number of the channels per each one of the at least one second cell block may be greater than a number of the channels per any one of the plurality of first cell blocks.

In example embodiments, at least one bit line may electrically connect to the plurality of channels in the plurality of first cells blocks that are below the bit line. The stacked structure may include a plurality of dielectric structures. Each one of the plurality of dielectric structures may surround a corresponding one of the plurality of channels. The plurality of dielectric structures may extend the first direction through the plurality of gate lines and insulating layers.

In example embodiments, the at least one second cell block may be a plurality of second cell blocks on the peripheral region of the substrate.

In example embodiments, a separation distance between the plurality of second cell blocks that neighbor each other may be greater than the separation distance between the plurality of first cell blocks that neighbor each other. The openings that separate the stacked structure into the plurality of second blocks may have a greater width than the openings that separate the stacked structure into the plurality of first blocks.

According to example embodiments, edge or peripheral portions of a substrate may be utilized as a dummy region so that defects or failures due to a stress concentrated on the edge or peripheral portions may be limited (and/or prevented) in a vertical memory device. In a formation of the vertical memory device, a mold block or a cell block formed on the edge portion may have a width or a pitch greater than that of a mold block or a cell block formed on a cell region, so that the mold or cell blocks on the edge portion may be limited (and/or prevented) from being leaned, collapsed or bended.

### BRIEF DESCRIPTION OF THE DRAWINGS

The foregoing and other features and advantages of inventive concepts will be apparent from the more particular description of non-limiting embodiments of inventive concepts, as illustrated in the accompanying drawings in which like reference characters refer to like parts throughout the different views. The drawings are not necessarily to scale, emphasis instead being placed upon illustrating principles of inventive concepts. In the drawings:

FIGS. 1 and 2 are a cross-sectional view and a top-plan view, respectively, illustrating a vertical memory device in accordance with example embodiments;

FIGS. 3 and 4 are a cross-sectional view and a top-plan view, respectively, illustrating a vertical memory device in accordance with example embodiments;

FIGS. 5 to 18 are cross-sectional views and a top-plan view illustrating a method of manufacturing a vertical memory device in accordance with example embodiments;

FIG. 19 is a cross-sectional view illustrating a vertical memory device in accordance with example embodiments;

FIGS. 20 to 24 are cross-sectional views illustrating a method of manufacturing a vertical memory device in accordance with example embodiments;

FIGS. 25 and 26 are a cross-sectional view and a top-plan view, respectively, illustrating a vertical memory device in accordance with example embodiments;

FIGS. 27 to 33 are cross-sectional views illustrating a method of manufacturing a vertical memory device in accordance with example embodiments;

FIGS. 34 and 35 are a cross-sectional view and a top-plan view, respectively, illustrating a vertical memory device in accordance with example embodiments;

FIGS. 36 to 40 are cross-sectional views illustrating a method of manufacturing a vertical memory device in accordance with example embodiments;

FIGS. 41 and 42 are a cross-sectional view and a top-plan view, respectively, illustrating a vertical memory device in accordance with example embodiments;

FIG. 43 is a top-plan view illustrating a vertical memory device in accordance with example embodiments;

FIG. 44 is a top-plan view illustrating a vertical memory device in accordance with example embodiments; and

FIG. 45 is a top-plan view illustrating a vertical memory device in accordance with example embodiments.

### DESCRIPTION OF EMBODIMENTS

Various example embodiments will be described more fully hereinafter with reference to the accompanying drawings, in which some example embodiments are shown. Inventive concepts may, however, be embodied in many different forms and should not be construed as limited to the example embodiments set forth herein. Rather, these example embodiments are provided so that this description will be thorough and complete, and will fully convey the scope of inventive concepts to those skilled in the art. In the drawings, the sizes and relative sizes of layers and regions may be exaggerated for clarity. Like reference numerals in the drawings denote like elements, and thus their description may be omitted.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” “includes”, and/or “including”, when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

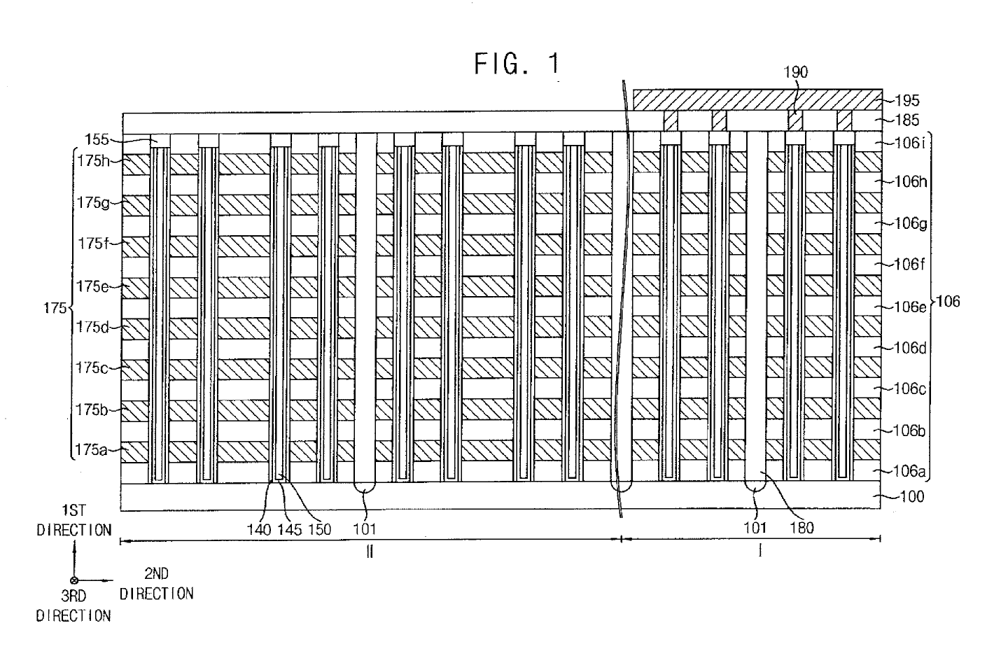

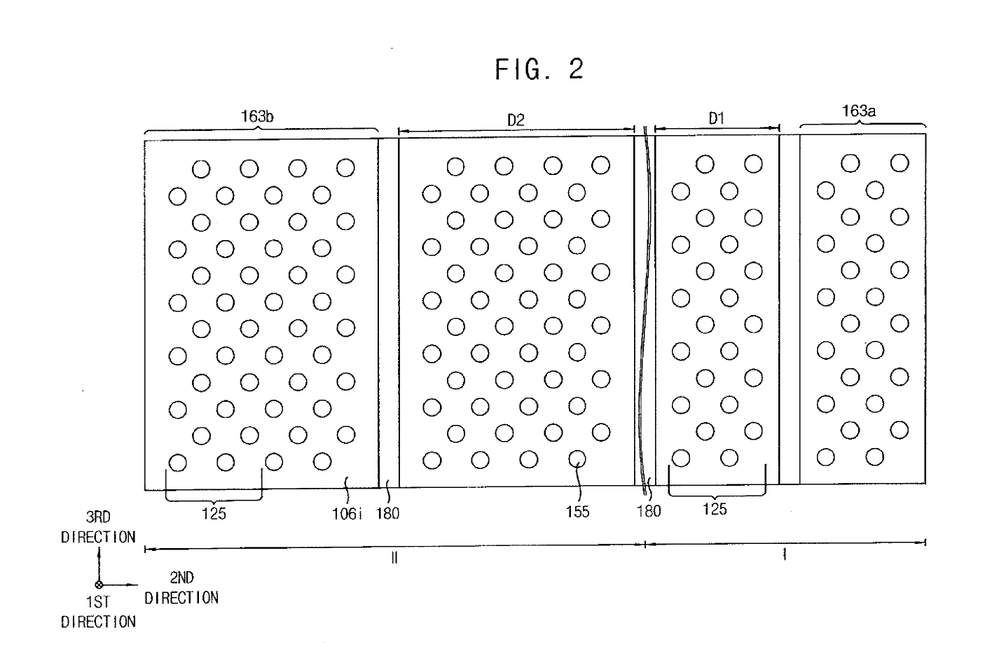

FIGS. 1 and 2 are a cross-sectional view and a top-plan view, respectively, illustrating a vertical memory device in accordance with example embodiments

For the convenience of explanation, an illustration of some elements of FIG. 1 including an upper insulation layer, a bit line and a bit line contact is omitted in FIG. 2.

In all figures in this specification, a direction substantially perpendicular to a top surface of a substrate is referred to as a first direction, and two directions substantially parallel to the top surface of the substrate and crossing each other are referred to as a second direction and a third direction. For example, the second and third directions are substantially perpendicular to each other. Additionally, a direction indicated by an arrow in the figures and a reverse direction thereof are considered as the same direction.

Referring to FIG. 1, the vertical memory device may include stacked structure on a substrate 100. The stacked structure may include a plurality of channels 145 protruding in the first direction from a top surface of the substrate 100, a dielectric structure 140 surrounding an outer sidewall of the channel 145, and gate lines 175 surrounding the channel 145 and spaced apart from each other in the first direction. A pad 155 may be disposed on the channel 145 and the dielectric layer structure 140. The vertical memory device may further include a bit line contact 190 in contact with the pad 155, and a bit line 195 electrically connected to with the bit line contact 190.

The substrate 100 may include a semiconductor material, e.g., single crystalline silicon or germanium. The substrate 100 may be divided into a central region I and a peripheral region II. In example embodiments, the central region I and the peripheral region II may serve as a cell region and a dummy region, respectively.

The channel 145 may be in contact with the top surface of the substrate 100 and have a hollow cylindrical shape or a cup shape. The channel 145 may include polysilicon or single crystalline silicon. The channel 145 may further include impurities (e.g., p-type impurities such as boron (B)).

A first filling layer pattern 150 may be formed in the channel 145. The first filling layer pattern 150 may have a pillar shape or a solid cylindrical shape. The first filling layer pattern 150 may include an insulation material, e.g., silicon oxide.

The first filling layer pattern 150 may be omitted, in which case, the channel 145 may have a pillar shape or a solid cylindrical shape. However, example embodiments are not limited thereto and the channel 145 may have other shapes (e.g., rectangular).

The dielectric layer structure 140 may be in contact with the outer sidewall of the channel 145. The dielectric layer structure 140 may have a cup shape of which a central bottom is opened, or a straw shape.

The dielectric layer structure 140 may include a tunnel insulation layer, a charge storage layer and a first blocking layer sequentially formed from the outer sidewall of the channel 145. The first blocking layer may include an oxide such as silicon oxide or a metal oxide including, e.g., a hafnium oxide or aluminum oxide. The charge storage layer may include a nitride such as silicon nitride or a metal oxide, and the tunnel insulation layer may include an oxide such as silicon oxide. For example, the dielectric layer structure 140 may have an oxide-nitride-oxide (ONO) layer structure.

The pad 155 may be formed on the first filling layer pattern 150, the channel 145 and the dielectric layer structure 140. The pad 155 may be electrically connected to the bit line 195 via the bit line contact 190. The pad 155 may serve as a source/drain region through which charges are moved or transferred to the channel 145. The pad 155 may include polysilicon or single crystalline silicon. The pad 155 may further include impurities (e.g., n-type impurities such as phosphorus (P) or arsenic (As)). The pad 155 may include impurities that are an opposite conductivity type (e.g., n-type) compared to impurities of the channel 145 (e.g., n-type).

Hereinafter, an arrangement of the channels 145 is described in detail with reference to FIG. 2. FIG. 2 illustrates an arrangement of the pads 155 which is substantially the same as the arrangement of the channels 145.

Referring to FIG. 2, a plurality of the channels 145 may be arranged in the third direction to form a channel row. A plurality of the channel rows may be arranged in the second direction to form a channel bundle 125.

In example embodiments, one channel bundle 125 may be defined by four channel rows as illustrated in FIG. 2. However, the number of the channel rows included one channel bundle 125 may be adjusted according to a circuit design or a structural design of the vertical memory device. For example, the one channel bundle 125 may include 2, 6 or 8 channel rows.

Referring now to FIG. 1, the gate lines 175 may be disposed on an outer sidewall of the dielectric layer structure 140 to be spaced apart from each other in the first direction. In example embodiments, each gate line 175 may partially surround the channels 145 included in the channel bundle 125 and may extend in the third direction.

The gate line 175 may include a metal or a metal nitride. For example, the gate line 175 may include the metal or the metal nitride having a low electrical resistance such as tungsten (W), tungsten nitride, titanium (Ti), titanium nitride, tantalum (Ta), tantalum nitride, platinum (Pt), etc. In example embodiments, the gate line 175 may have a multi-layered structure including a barrier layer formed of the metal nitride, and a metal layer.

Two lowermost gate lines 175a and 175b may serve as a ground selection lines (GSLs), four gate lines 175c, 175d, 175e and 175f on the GSL may serve as word lines, and two uppermost gate lines 175g and 175h on the word lines may serve as string selection lines (SSLs). In example embodiments, the gate lines 175 disposed on the peripheral region II may serve as dummy gate lines.

As described above, the GSL, the word line and the SSL may be formed at 2 levels, 4 levels and 2 levels, respectively. However, the numbers of the levels at which the GSL, the word line and the SSL are formed are not specifically limited. In example embodiments, each of the GSL and the SSL may be formed at a single level, and the word lines may be formed at 2, 8 or 16 levels. The stacked number of the gate lines 175 may be determined in consideration of, e.g., an integration degree and the circuit design of the vertical memory device.

Insulating interlayer patterns 106 may be disposed between the gate lines 175 neighboring in the first direction. The insulating interlayer patterns 106 may include a silicon oxide based material, e.g., silicon dioxide (SiO₂), silicon oxycarbide (SiOC) or silicon fluorooxide (SiOF). The gate lines 175 included in a cell block may be insulated from each other by the insulating interlayer patterns 106.

The cell block may be defined by second filling layer patterns 180 adjacent to each other in the second direction. The second filling layer pattern 180 may extend through the gate lines 175 and the insulating interlayer patterns 106 in the first direction. The second filling layer pattern 180 may also extend in the third direction and may serve as a gate line cut pattern. The second filling layer pattern 180 may include an insulation material, e.g., silicon oxide.

As illustrated in FIG. 2, the cell block may include a first cell block 163a disposed on the central region I and a second cell block 163b disposed on the peripheral region II. The cell block may include the channel bundle 125, and the pads 155, the first filling layer patterns 150 and the dielectric layer patterns 140 corresponding to the channel bundle 125. The cell block may also include the gate lines 175 and the insulating interlayer patterns 106 surrounding the channel bundle 125. FIGS. 1 and 2 illustrate two first cell blocks 163a on the central region I, however, additional channel bundles 163a may be arranged on the central region I in the second direction.

In example embodiments, the number of the channel bundle 125 included in the second cell block 163b may be greater than the number of the channel bundle 125 included in the first cell block 163a. A width of the second cell block 163b in the second direction (denoted as a second width “D2”) may be greater than a width of the first cell block 163a in the second direction (denoted as a first width “D1”). The first width D1 may be defined as a distance between the adjacent second filling layer patterns 180 on the central region I. The second width D2 may be defined as a distance between the adjacent second filling layer patterns 180 on the peripheral region II.

In example embodiments, for example as illustrated in FIG. 2, the first cell block 163a may include one channel bundle 125, and the second cell block 163b may include two channel bundles 125. In this case, the second width D2 may be substantially double the first width D1. For example, a ratio of the second width D2 and the first width D1 may be about 2.

However, the ratio of the second width D2 and the first width D1 may not be limited a specific value. In example embodiments, the ratio of the second width D2 and the first width D1 may be an integer equal to or greater than 2. For example, the second cell block 163b may include 3 or 4 channel. In this case, the ratio of the second width D2 and the first width D1 may be substantially 3 or 4.

As illustrated in FIG. 1, an impurity region 101 may be formed an upper portion of the substrate 100 adjacent to the second filling layer pattern 180. The impurity region 101 may extend in the third direction and may serve as a common source line (CSL) of the vertical memory device. The impurity region 101 may include n-type impurities such as phosphorous or arsenic. In example embodiments, a metal silicide pattern, e.g., a cobalt silicide pattern and a nicked silicide pattern may be further formed on the impurity region 101.

An upper insulation layer 185 may be formed on the uppermost insulating interlayer pattern 106i, the pad 155 and the second filling layer pattern 180. The bit line contact 190 may be formed through the upper insulation layer 185 to contact the pad 155. The bit line 195 may be disposed on the upper insulation layer 185 to contact the bit line contact 190. The bit line 195 may extend in the second direction to be electrically connected to a plurality of the pads 155. A plurality of the bit lines 195 may be arranged in the third direction.

The upper insulation layer 185 may include an insulation material, e.g., silicon oxide. In example embodiments, the second filling layer pattern 180 and the upper insulation layer 195 may be merged or integral with each other. The bit line contact 190 and the bit line 195 may include a metal, a metal nitride or a doped polysilicon.

In example embodiments, the peripheral region II may serve as a dummy region, the bit line contact 190 and the bit line 195 may not be electrically connected to the pad 155 and/or the channel 145 disposed on the peripheral region II. Thus, an electrical signal from the bit line 190 and the bit line 195 may not be transferred to the pad 155, the channel 145 and the gate lines 175 disposed on the peripheral region II.

For example, the bit line contacts 190 may be arranged only on the central region I as illustrated in FIG. 1. For example, the bit line contact 190 may be formed only on the pad 155 of the central region I. The bit line 195 may extend only on the central region I and may not extend over the peripheral region II. However, the bit line 195 may also extend over the peripheral region II because the bit line contacts 190 may be formed only on the central region I. Thus, the channel 145 and the gate line 175 disposed on the peripheral region II may not participate in an operation of the vertical memory device.

In example embodiments, the bit line contacts 190 may be formed throughout the central and peripheral regions I and II, and the bit lines 195 may be disposed only on the central region I.

As described above, the cell block of the peripheral region II may have a width greater than that of the cell block of the central region I. In this case, a distance between the second filling layer patterns 180 on the peripheral region II may be greater than that on the central region I.

Accordingly, defects or failures frequently occurring on the peripheral region II including a bending, a leaning and a collapse of the cell block may be avoided. As an aspect ratio of the cell block becomes greater, the defects or the failures may be exacerbated. According to example embodiments, the width of the cell block may be controlled to prevent the defects or the failures. The peripheral region II may be provided as the dummy region. Thus, even though a plurality of the channel bundles 125 forms a group by one cell block, the operation of the vertical memory device may not be affected by the cell block of the peripheral region II.

In example embodiments, the channels 145, dielectric layer patterns 140, portions of the gate lines 175, and portions of the insulating interlayer patterns 106 in the first cell block may be referred to as first channels, first dielectric layer patterns, first gate lines, and first insulating interlayer patterns, respectively. Similarly, the channels 145, dielectric layer patterns 140, portions of the gate lines 175, and portions of the insulating interlayer patterns 106 in the second cell block may be referred to as second channels, second dielectric layer patterns, second gate lines, and second insulating interlayer patterns, respectively.

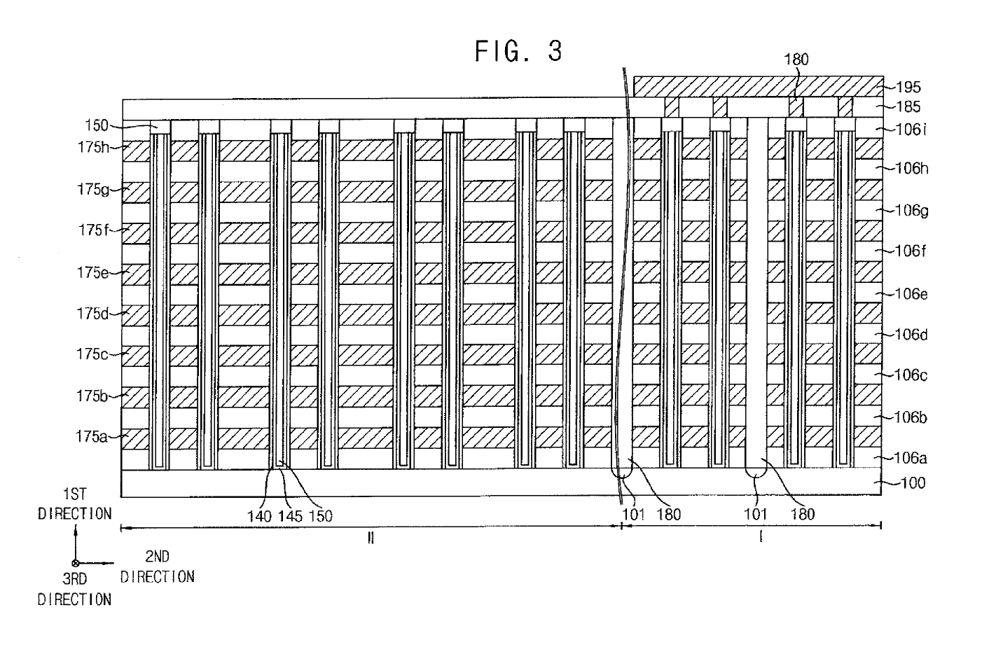

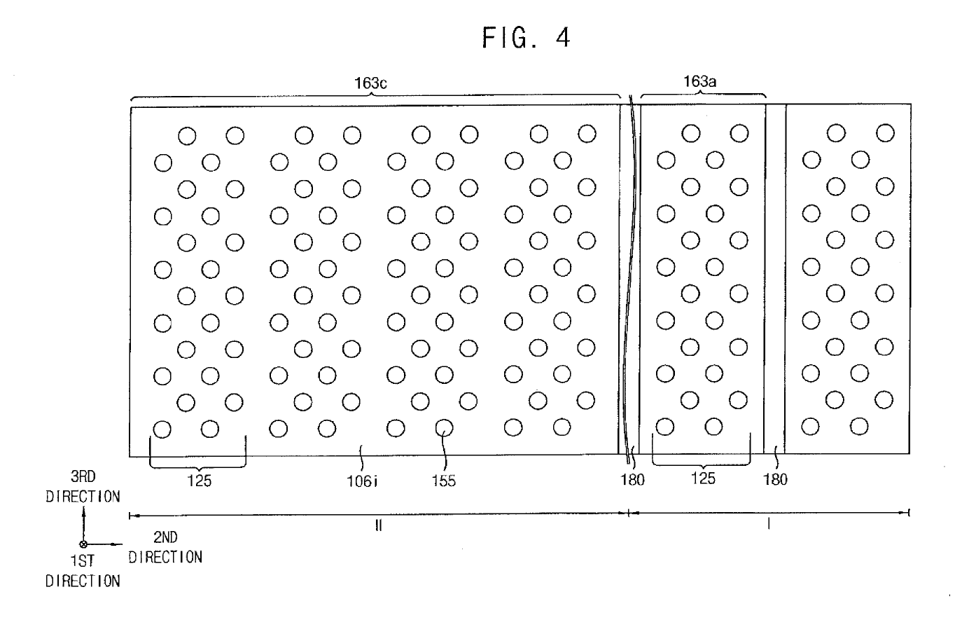

FIGS. 3 and 4 are a cross-sectional view and a top-plan view, respectively, illustrating a vertical memory device in accordance with example embodiments. For the convenience of explanation, an illustration of some elements of FIG. 3 including an upper insulation layer, a bit line and a bit line contact is omitted in FIG. 2.

The vertical memory device of FIGS. 3 and 4 may have elements and/or constructions substantially the same as or similar to those illustrated with reference to FIGS. 1 and 2 except for constructions of a second cell block and a second filling layer pattern. Thus, detailed descriptions on repeated elements and structures are omitted.

Referring to FIGS. 3 and 4, one second cell block 163c including a plurality of channel bundles 125 may be disposed on a peripheral region II. In this case, a plurality of first cell blocks 163a may be arranged on a central region I according to a memory cell design, and all the channel bundles 125 on the peripheral region II may be formed as one group by the one second cell block 163c. Thus, a bending or a leaning of the cell block occurring on the peripheral region II may be effectively suppressed.

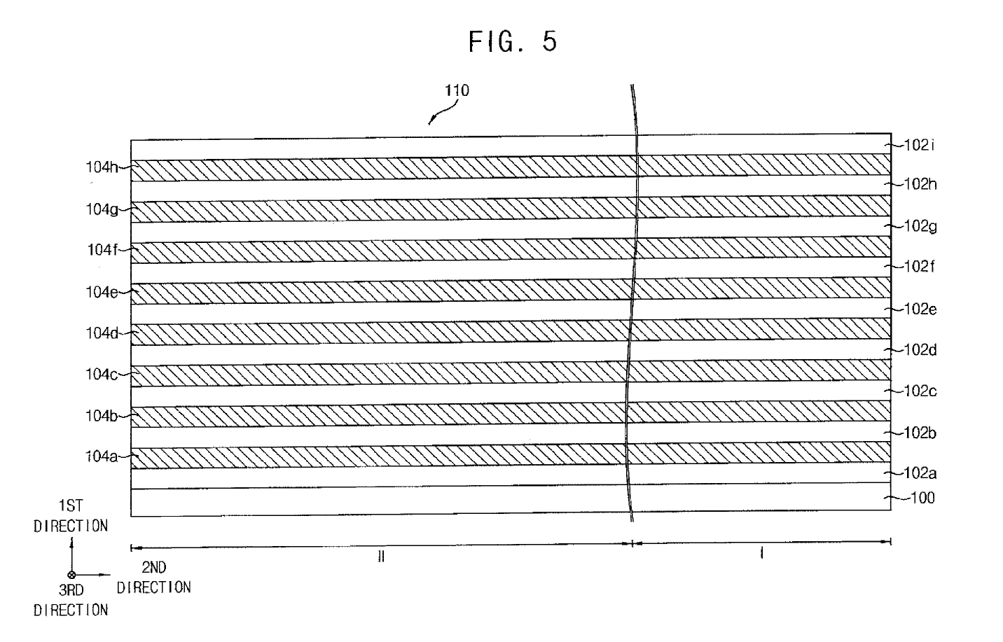

FIGS. 5 to 18 are cross-sectional views and a top-plan view illustrating a method of manufacturing a vertical memory device in accordance with example embodiments. For example, FIGS. 5 to 18 illustrate a method of manufacturing the vertical memory device of FIGS. 1 and 2 or FIGS. 3 and 4.

Referring to FIG. 5, insulating interlayers 102 and sacrificial layers 104 may be formed alternately and repeatedly on a substrate 100 to form a mold structure 110.

The substrate 100 may include a semiconductor material, e.g., single crystalline silicon and/or germanium. The substrate 100 may include a central region I and a peripheral region II. In example embodiments, the central region I and the peripheral region II may correspond to a cell region and a dummy region, respectively.

The peripheral region II may be defined as a region of the substrate 100 at peripheral or lateral portions of the central region I. For the convenience of explanation, FIG. 5 illustrates one peripheral region II at a left-side of the central region I.

In example embodiments, the insulating interlayer 102 may be formed using an oxide-based material. For example, the insulating interlayer 102 may be formed using a silicon oxide based material, e.g., silicon dioxide, silicon oxycarbide or silicon fluorooxide. The sacrificial layer 104 may be formed using a material that may have a high etching selectivity with respect to the insulating interlayer 102. The sacrificial layer 104 may be formed using a nitride-based material, e.g., a silicon nitride or silicon boronitride (SiBN).

The insulating interlayer 102 and the sacrificial layer 104 may be formed by, e.g., a chemical vapor deposition (CVD) process, a plasma enhanced chemical vapor deposition (PECVD) process, an atomic layer deposition (ALD) process, a spin coating process, etc. A lowermost insulating interlayer 102a may be formed by performing a thermal oxidation process on the substrate 100.

The sacrificial layers 104 may be removed in a subsequent process to provide spaces for a GSL, a word line and an SSL. Thus, the number of the insulating interlayers 102 and the sacrificial layers 104 may be adjusted in consideration of the number of the GSL, the word line and the SSL. In example embodiments, each of the GSL and the SSL may be formed at 2 levels, and the word line may be formed at 4 levels. Accordingly, the sacrificial layers 104 may be formed at 8 levels, and the insulating interlayers 102 may be formed at 9 levels. In example embodiments, each of the GSL and the SSL may be formed at a single level, and the word line may be formed at 2, 8 or 16 levels. In this case, the sacrificial layers 104 may be formed at 4, 10 or 18 levels, and the insulating interlayers 102 may be formed at 5, 11 or 19 levels. However, the number of the GSL, the SSL and the word line may not be limited herein.

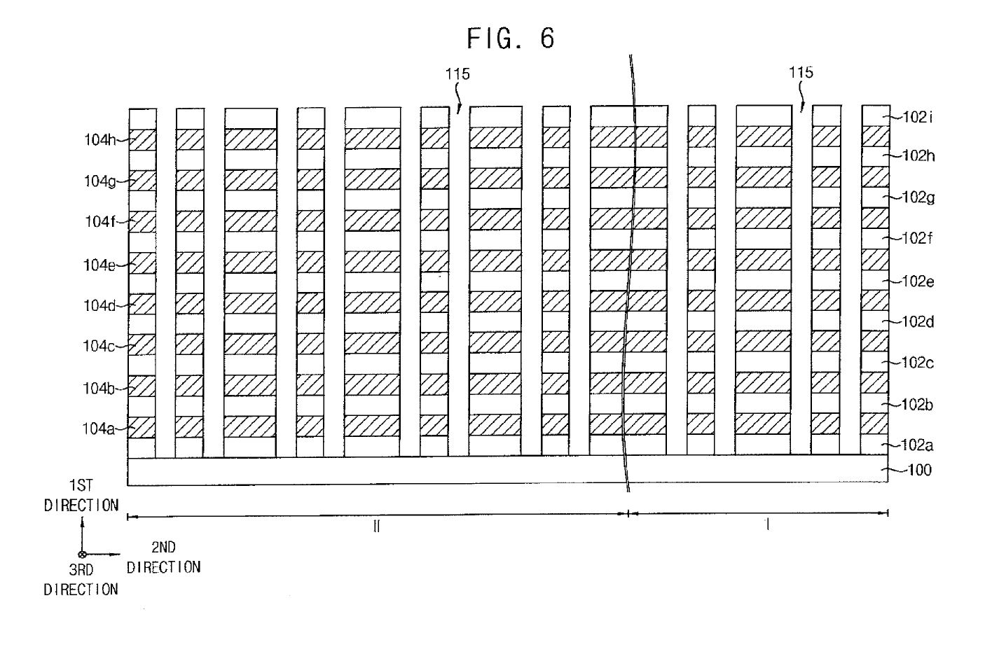

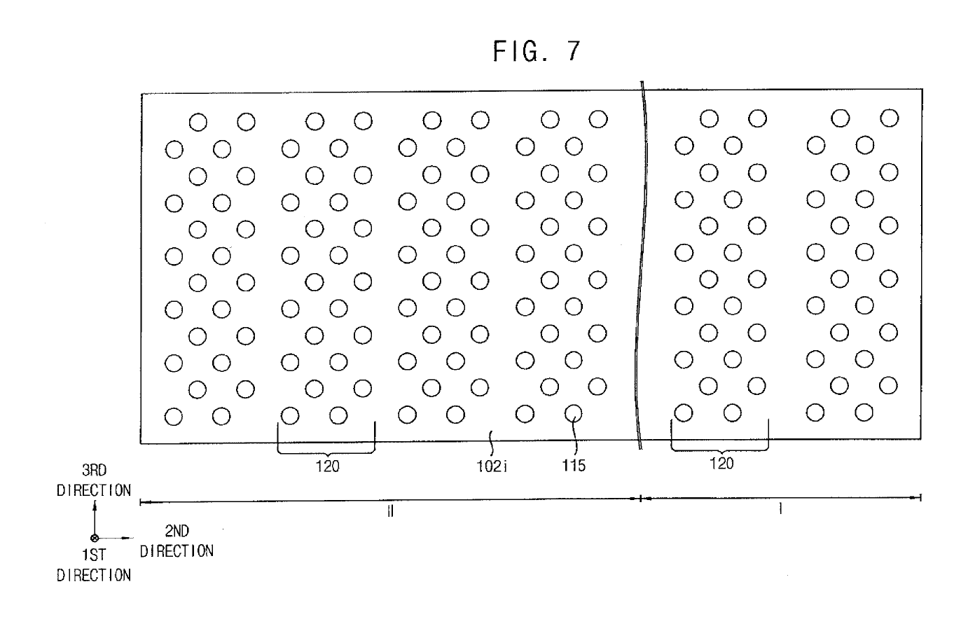

Referring to FIG. 6 and FIG. 7 that is a top plan view of FIG. 6, a plurality of channel holes 115 may be formed through the mold structure 110.

In example embodiments, a hard mask (not illustrated) may be formed on an uppermost insulating interlayer 102i. The insulating interlayers 102 and the sacrificial layers 104 may be partially removed using the hard mask as an etching mask to form the channel hole 115. A top surface of the substrate 100 may be exposed by the channel hole 115 and the channel hole 115 may extend in the first direction with respect to the top surface of the substrate 100. A sidewall of the channel hole 115 may be substantially vertical with respect to the top surface of the substrate 100. However, the sidewall of the channel hole 115 may be tapered with respect to the top surface of the substrate 100 due to characteristics of a dry etching process.

The hard mask may be formed using a material having an etching selectivity with respect to the insulating interlayer 102 and the sacrificial layer 104. For example, the hard mask may be formed using polysilicon or amorphous silicon. In example embodiments, the hard mask may be formed using a silicon-based or a carbon based spin-on hard mask (SOH) material. The hard mask may be removed by, e.g., an ashing process and/or a strip process after the formation of the channel holes 115.

As illustrated in FIG. 7, a plurality of the channel holes 115 may be formed in the third direction to form a channel hole row. A plurality of the channel hole rows may be formed in the second direction to form a channel hole bundle 120. In example embodiments, a plurality of the channel hole bundles 120 may be regularly arranged throughout the central region I and the peripheral region II.

In example embodiments, 4 channel hole rows may form one channel hole bundle 120. However, the number of the channel hole rows included in the one channel hole bundle 120 may not be limited herein. For example, the one channel hole bundle 120 may include 2, 6 or 8 channel hole rows.

The channel holes 115 included in the channel hole bundle 120 may face each other in a zigzag arrangement. Thus, the number of the channel holes 115 formed in a unit area of the substrate 100 may be increased.

FIG. 7 illustrates that four channel hole bundles 120 are arranged on the peripheral region II. However, the number of the channel hole bundles 120 is not limited to a specific number. For example, 2, 6 or 8 channel hole bundles 120 may be formed on the peripheral region II. A plurality of the channel hole bundles 120 may be also formed on the central region I in consideration of an integration degree and a capacity of the vertical memory device.

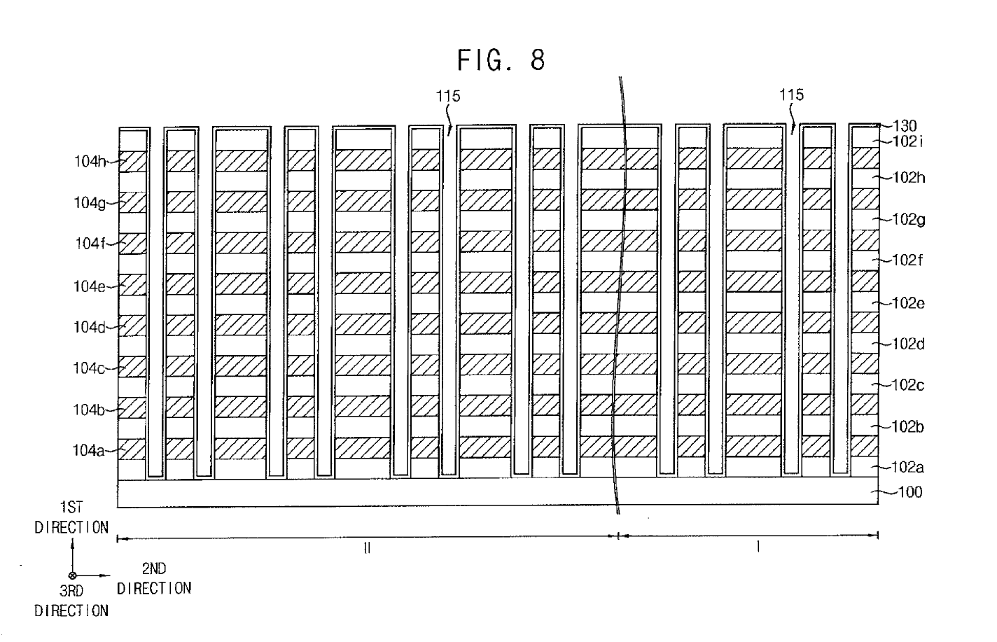

Referring to FIG. 8, a dielectric layer 130 may be formed on the sidewalls and bottoms of the channel holes 115 and on the uppermost insulating interlayer 102i.

In example embodiments, the dielectric layer 130 may be obtained by sequentially forming a first blocking layer, a charge storage layer and a tunnel insulation layer.

The first blocking layer may be formed using an oxide, e.g., silicon oxide, the charge storage layer may be formed using silicon nitride or a metal oxide, and the tunnel insulation layer may be formed using an oxide, e.g., silicon oxide. In example embodiments, the dielectric layer 130 may have an oxide-nitride-oxide (ONO) layer structure. The first blocking layer, the charge storage layer and the tunnel insulation layer may be formed by a CVD process, a PECVD process, an ALD process, etc.

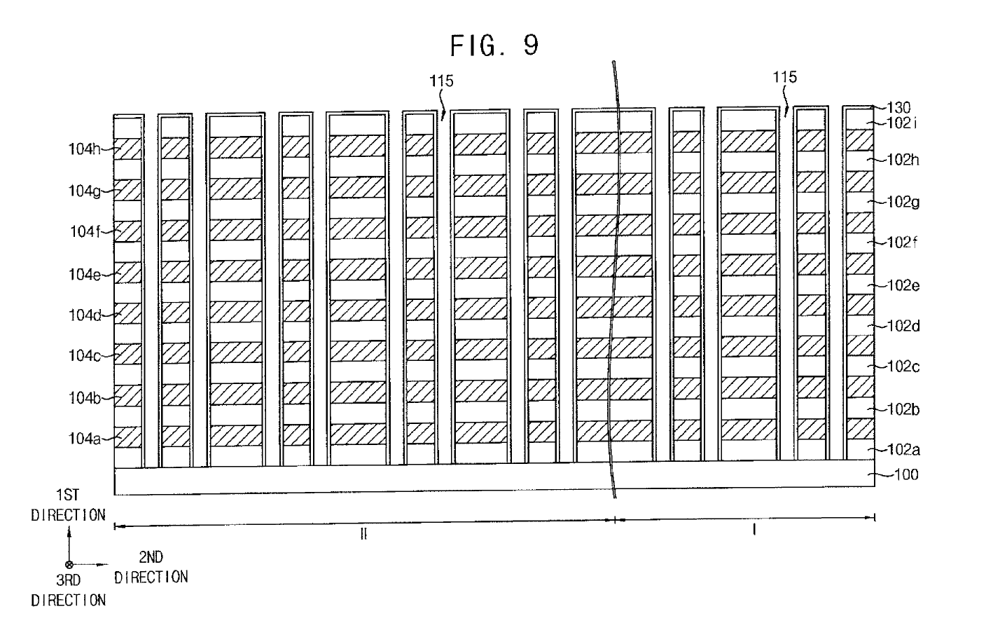

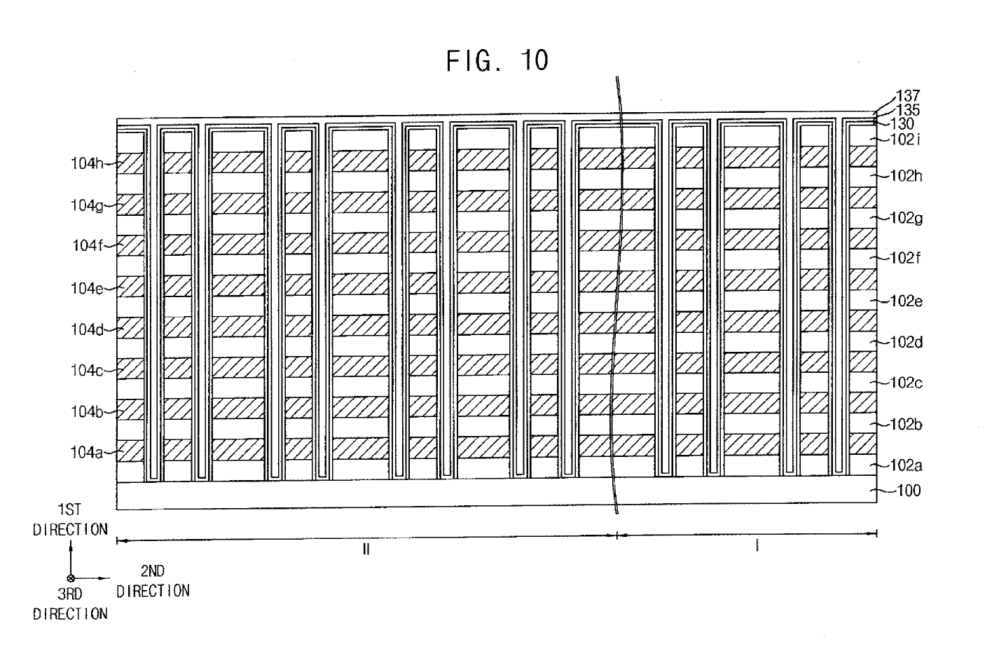

Referring to FIG. 9, bottoms of the dielectric layer 130 may be partially removed by, e.g., an etch-back process to partially expose the top surface of the substrate 100. Accordingly, the bottoms of the dielectric layer 130 may be opened in the channel holes 115.

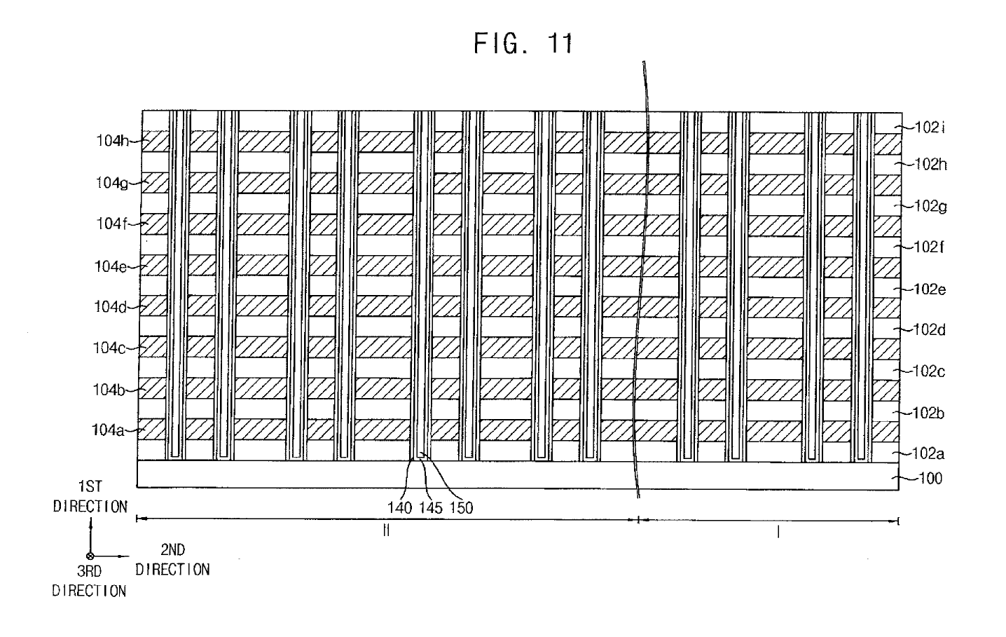

Referring to FIG. 10, a channel layer 135 may be formed on the dielectric layer 130 and the exposed top surface of the substrate 100, and then a first filling layer 137 may be formed on the channel layer 135 to sufficiently fill a remaining portion of the channel hole 115. The channel layer 135 may be formed using polysilicon or amorphous silicon which is optionally doped with impurities. In example embodiments, a heat treatment or a laser beam irradiation may be further performed on the channel layer 135. In this case, the channel layer 135 may include single crystalline silicon and defects in the channel layer 135 may be cured. The first filling layer 137 may be formed using an insulation material, e.g., silicon oxide or silicon nitride.

The channel layer 135 and the first filling layer 137 may be formed by a CVD process, a PECVD process, an ALD process, etc.

In example embodiments, the channel layer 135 may be formed to fully fill the channel hole 115. In this case, the formation of the first filling layer 137 may be omitted.

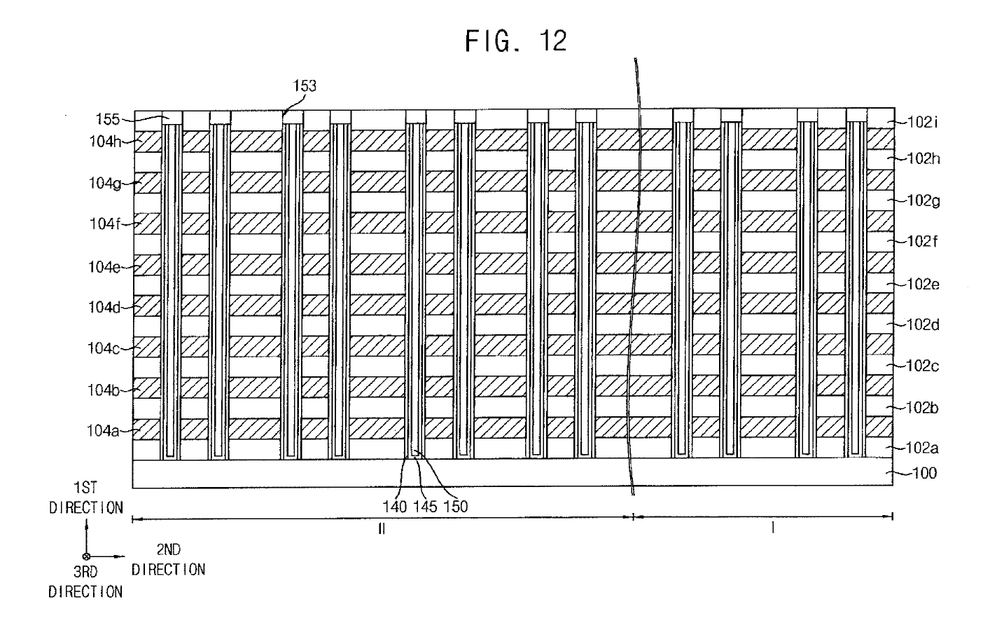

Referring to FIG. 11, the first filling layer 137, the channel layer 135 and the dielectric layer 130 may be planarized until the uppermost insulating interlayer 102i is exposed to form a dielectric layer structure 140, a channel 145 and a first filling layer pattern 150 sequentially stacked in the channel hole 115. The planarization process may include an etch-back process or a CMP process.

In example embodiments, the dielectric layer structure 140 may have a substantially hollow cylindrical shape or a straw shape. The channel 145 may have a substantial cup shape. The first filling layer pattern 150 may have a substantially solid cylindrical shape or a substantially pillar shape.

In the case that the channel layer 135 fully fills the channel hole 115, the first filling layer pattern 150 may be omitted and the channel 145 may have a substantially solid cylindrical shape or a substantially pillar shape.

A channel array comparable to an arrangement of the channel holes 115 may be formed. For example, a channel row and a channel bundle comparable to the channel hole row and the channel hole bundle, respectively, may be formed.

Referring to FIG. 12, a pad 155 capping an upper portion of the channel hole 115 may be formed on the dielectric layer structure 140, the channel 145 and the first filling layer pattern 150.

In example embodiments, upper portions of the dielectric layer structure 140, the channel 145 and the first filling layer pattern 150 may be removed by an etch-back process to form a recess 153. A pad layer sufficiently filling the recess 153 may be formed on the dielectric layer structure 140, the channel 145, the first filling layer pattern 150 and the uppermost insulating interlayer 102i. An upper portion of the pad layer may be planarized until a top surface of the uppermost insulating interlayer 102i is exposed to obtain the pad 155. In example embodiments, the pad layer may be formed using polysilicon or polysilicon doped with n-type impurities by, e.g., a CVD process. In example embodiments, a preliminary pad layer may be formed using amorphous silicon, and then a crystallization process may be performed thereon to form the pad layer. The planarization process may include a CMP process.

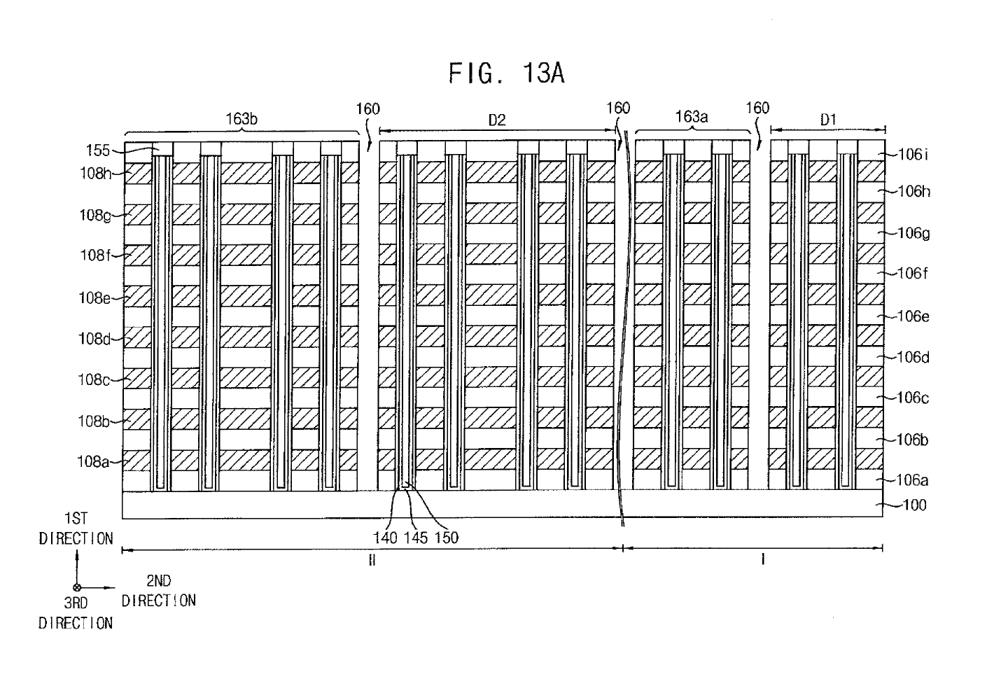

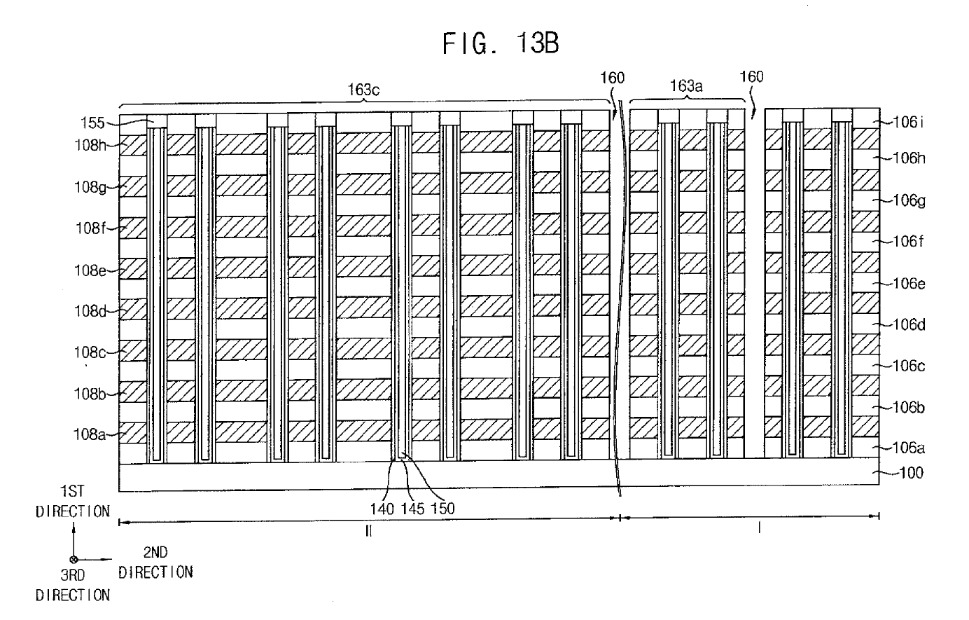

Referring to FIG. 13A, the mold structure 110 may be partially etched to form openings 160.

For example, a mask pattern (not illustrated) covering the pads 155 may be formed on the uppermost insulating interlayer 102i. A dry etching process may be performed using the mask pattern as an etching mask, such that portions of the insulating interlayers 102 and the sacrificial layers 104 between the neighboring channel rows may be removed to form the openings 160. The hard mask may be formed using a photoresist material or an SOH material. The hard mask may be removed by an ashing process and/or a strip process after the formation of the openings 160.

In example embodiments, the opening 160 may be formed between the neighboring channel bundles. The opening 160 may extend in the third direction and the top surface of the substrate 100 may be exposed through the opening 160.

The insulating interlayers 102 and the sacrificial layers 104 may be changed into insulating interlayer patterns 106 and sacrificial layer patterns 108, respectively, by the formation of the openings 155. A cell block may be defined between the openings 160 neighboring in the second direction. The cell block may include a first cell block 163a and a second cell block 163b formed on the central region I and the peripheral region II, respectively. The cell block may include the channel bundle, and the pads 155, the first filling layer pattern 150 and the dielectric layer structure 140 included in the channel bundle. The cell block may also include the insulating interlayer patterns 106 and the sacrificial layer patterns 108 surrounding the channel bundle and extending in the third direction.

In example embodiments, a distance between the openings 160 neighboring on the central region I (denoted as a first width “D1”) may be smaller than a distance between the openings 160 neighboring on the peripheral region II (denoted as a second width “D2”). The first width D1 and the second width D2 may be substantially the same as a width of the first cell block 163a and a width of the second cell block 163b, respectively.

In a manufacture of the vertical memory device, a plurality of cell blocks may be formed on the substrate 100. The cell block may have a multi-stacked structure including a plurality of insulation layers. Thus, as an aspect ratio of the cell block becomes greater, the cell block may become vulnerable to thermal and/or mechanical stress. The stress may be easily concentrated on a peripheral portion or an edge portion of the substrate 100. Accordingly, the cell block formed on the peripheral portion or the edge portion may be bended, leaned or collapsed. In this case, a misalignment may be caused in a subsequent process for forming, e.g., contacts or wirings, and a collision between the neighboring cell blocks may occur.

According to example embodiments, the width of the second cell block 163b formed on the peripheral region II (e.g., the second width D2) may be greater than the width of the first cell block 163a formed on the central region I (e.g., the first width D1). Thus, a bending, a leaning or a collapse of the cell block caused by a concentration of the stress on the peripheral region II may be limited (and/or prevented).

As illustrated in FIG. 13A, the first cell block 163a may include one channel bundle, and the second cell block 163b may include two channel bundles. In this case, the second width D2 may be substantially double the first width D1.

In example embodiments, a ratio of the second width D2 and the first width D1 may be an integer equal to or greater than 2. For example, the second cell block 163b may include 3 or 4 channel bundles. In this case, the ratio of the second width D2 and the first width D1 may be substantially 3 or 4.

Referring to FIG. 13B, one cell block 163c including a plurality of the channel bundles may be formed on the peripheral region II. In this case, a plurality of the first cell blocks 163a may be formed on the central region I according to a memory cell design, and all the channel bundles on the peripheral region II may be formed as one group by the one second cell block 163c. Thus, the bending or the leaning of the cell block occurring on the peripheral region II may be effectively suppressed.

As described above, the central region I and the peripheral region II may be provided as the cell region and the dummy region, respectively. Thus, even though a plurality of the channel bundles forms a group by one cell block, the operation of the vertical memory device may not be affected by the cell block of the peripheral region II.

Hereinafter, subsequent processes are described based on the structure of FIG. 13A.

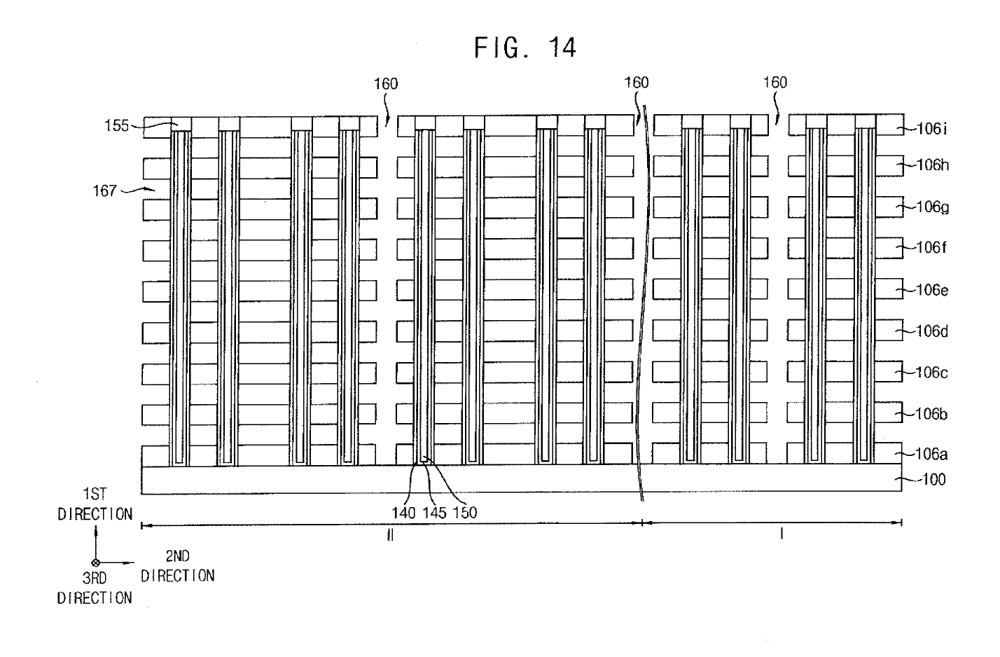

Referring to FIG. 14, the sacrificial layer patterns 108, sidewalls of which are exposed by the openings 160 may be removed. For example, the sacrificial layer patterns 108 may be removed by a wet etching process using an etchant solution that may contain phosphoric acid and/or sulfuric acid.

By the removal of the sacrificial layer patterns 108, gaps 167 may be defined between the insulating interlayer patterns 106 adjacent in the first direction. An outer sidewall of the dielectric layer structure 140 may be partially exposed by the gaps 167.

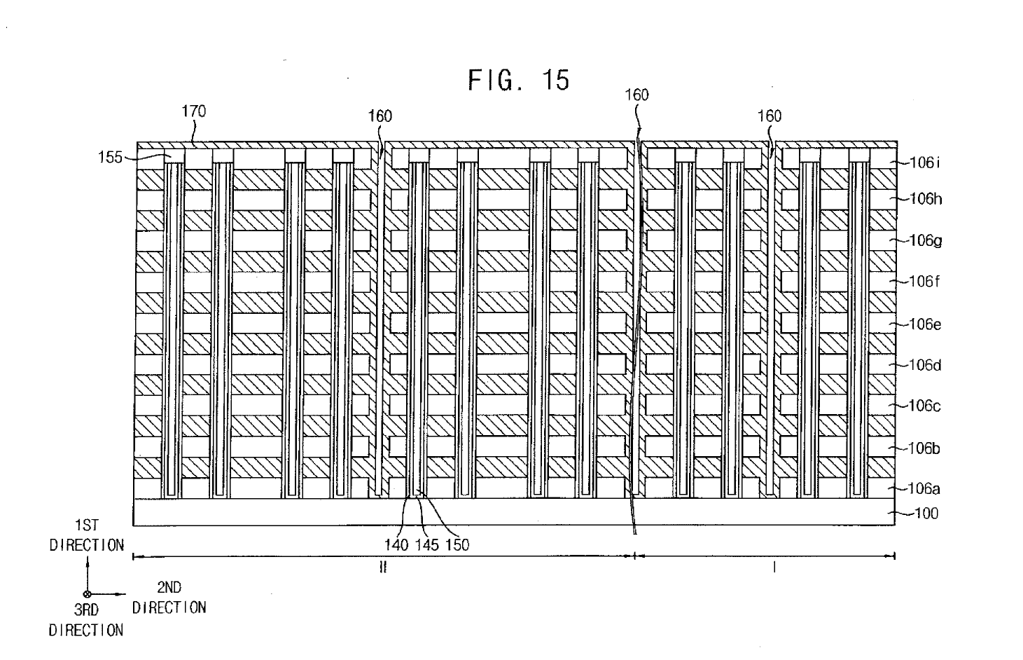

Referring to FIG. 15, a gate electrode layer 170 may be formed on the sidewall of the dielectric layer structure 140, surfaces of the insulating interlayer patterns 106, the top surface of the substrate 100 and a top surface of the pad 150. The gate electrode layer 170 may sufficiently fill the gaps 167 and may partially fill the openings 160.

The gate electrode layer 170 may be formed using a metal or a metal nitride. For example, the gate electrode layer 170 may be formed using tungsten, tungsten nitride, titanium, titanium nitride, tantalum, tantalum nitride, platinum, etc. In example embodiments, the gate electrode layer 170 may be formed as a multi-layered structure including a barrier layer formed of the metal nitride, and a metal layer. The gate electrode layer 170 may be formed by a CVD process, a PECVD process, an ALD process, a physical vapor deposition (PVD) process, a sputtering process, etc.

In example embodiments, a second blocking layer (not illustrated) may be further formed along inner walls of the gaps 167 and the surfaces of the insulating interlayer patterns 106 before forming the gate electrode layer 170. The second blocking layer may be formed using silicon oxide or a metal oxide by, e.g., a CVD process, a PECVD process or an ALD process.

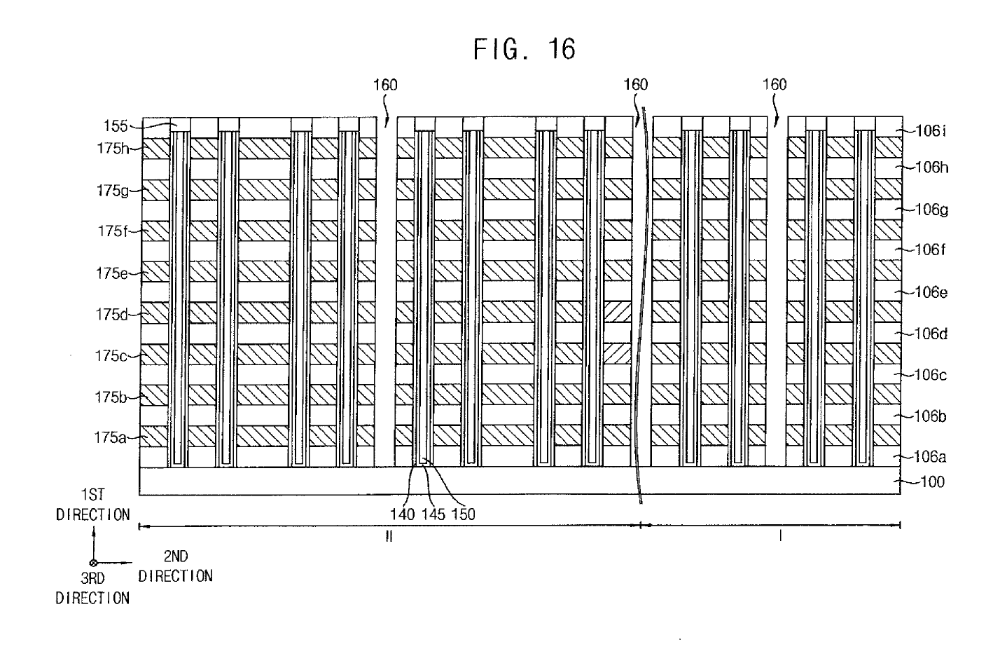

Referring to FIG. 16, the gate electrode layer 170 may be partially removed to form a gate line 175 in each gap 167.

For example, an upper portion of the gate electrode layer 170 may be planarized until an uppermost insulating interlayer pattern 106i is exposed. A portion of the gate electrode layer 170 formed in the opening 160 may be etched to obtain the gate lines 175.

In example embodiments, the planarization process may include a CMP process. The gate electrode layer 170 may be partially etched by a wet etching process using an etchant solution that may contain hydrogen peroxide (H₂O₂).

The gate lines 175 may include the GSL, the word line and the SSL sequentially stacked and spaced apart from each other in the first direction. For example, two lowermost gate lines 175a and 175b may serve as the GSL. Four gate lines 175c, 175d, 175e and 175f on the GSL may serve as the word lines. Two uppermost gate lines 175g and 175h on the word lines may serve as the SSL. The gate lines 175 formed on the peripheral region II may be defined as dummy gate lines. The operation of the vertical memory device may not be affected by the dummy gate lines.

The gate line 175 at each level may surround the dielectric layer structure 140 and extend in the third direction. The gate line 175 at the same level of the one cell block may be provided as a single, unitary member to surround the dielectric layer structure 140.

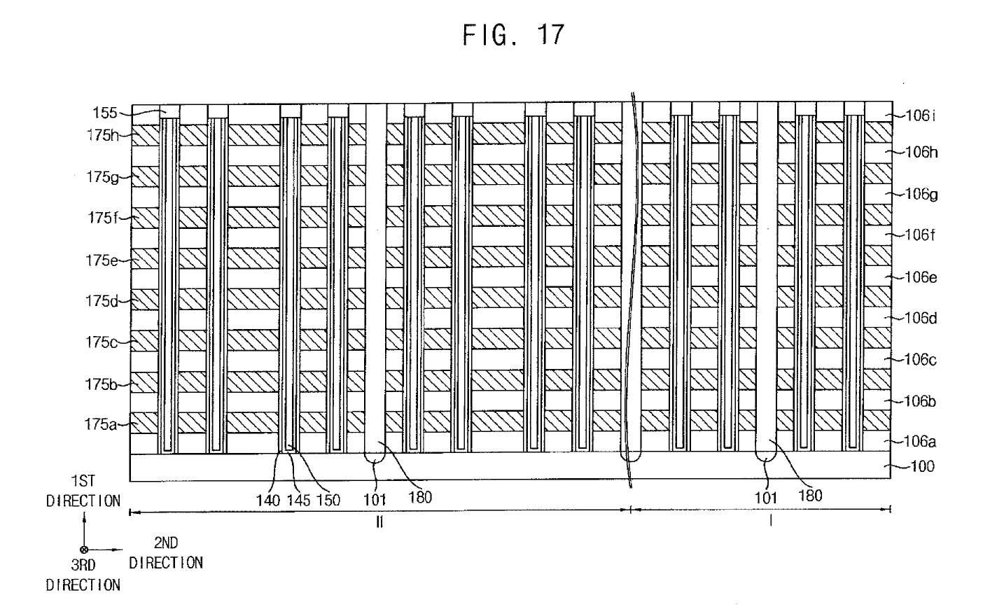

Referring to FIG. 17, an impurity region 101 may be formed at an upper portion of the substrate 100 exposed by the opening 160, and a second filling layer pattern 180 filling the opening 160 may be formed on the impurity region 101.

For example, an ion implantation mask (not illustrated) covering the pads 155 may be formed on the uppermost insulating interlayer pattern 106i. N-type impurities such as phosphorous or arsenic may be implanted through the opening 160 to form the impurity region 101. The impurity region 101 may extend in the third direction and serve as a CSL.

In example embodiments, a metal silicide pattern, e.g., a cobalt silicide pattern or a nickel silicide pattern may be further formed on the impurity region 101.

A second filling layer may be formed on the substrate 100, the uppermost insulating interlayer pattern 106i and the pad 155 to sufficiently fill the openings 160. An upper portion of the second filling layer may be planarized by, e.g., a CMP process or an etch-back process until the uppermost insulating interlayer pattern 106i is exposed to form the second filling layer pattern 180. The second filling layer may be formed using an insulation material, e.g., silicon oxide by, e.g., a CVD process.

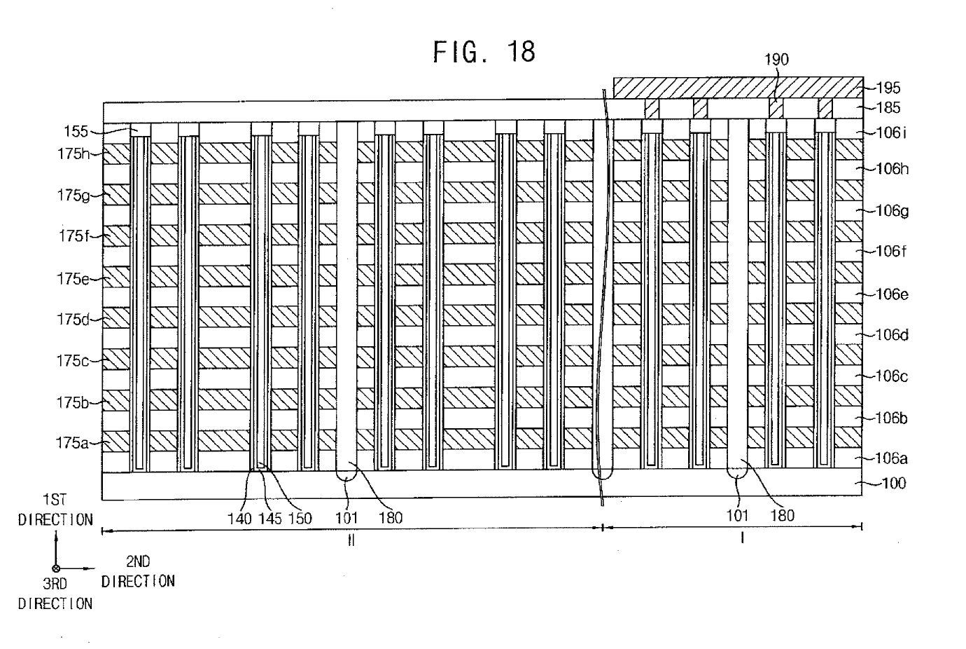

Referring to FIG. 18, an upper insulation layer 185 may be formed on the uppermost insulating interlayer pattern 106i, the second filling layer pattern 180 and the pad 155. The upper insulation layer 185 may be formed using an insulation material, e.g., silicon oxide by, e.g., a CVD process.

In example embodiments, the second filling layer may be formed to sufficiently fill the openings 160 and cover the uppermost insulating interlayer pattern 106i and the pads 155. In this case, the formation of the upper insulation layer 185 may be omitted.

A bit line contact 190 may be formed through the upper insulation layer 185 to contact the pad 155. A bit line 195 may be formed on the upper insulation layer 185 to be electrically connected to the bit line contact 190. The bit line contact 190 and the bit line 195 may be formed using a metal, a metal nitride or doped polysilicon by a PVD process, an ALD process or a sputtering process.

A plurality of the bit line contacts 190 may be formed according to an arrangement of the pads 155 to form a bit line contact array. The bit line 195 may extend in the second direction to be electrically connected to a plurality of the pads 155 via the bit line contacts 190. A plurality of the bit lines 195 may be formed in the third direction.

In example embodiments, the bit line contacts 190 may be formed only on the central region I as illustrated in FIG. 18. For example, the bit line contacts 190 may be formed only on the pads 155 of the central region I. The bit line 195 may extend on the central region I and may not extend over the peripheral region II. However, the bit line 195 may extend over the peripheral region II, because the bit line contacts 190 are formed only on the central region I. Thus, the channels 145 and the gate lines 175 formed on the peripheral region II may not participate in the operation of the vertical memory device.

In example embodiments, the bit line contacts 190 may be formed throughout the central region I and the peripheral region II, and the bit line 195 may extend only on the central region I.

In example embodiments, in the case that the one second cell block 163c is formed on the peripheral region II as illustrated in FIG. 13B, the vertical memory device of FIG. 3 may be obtained.

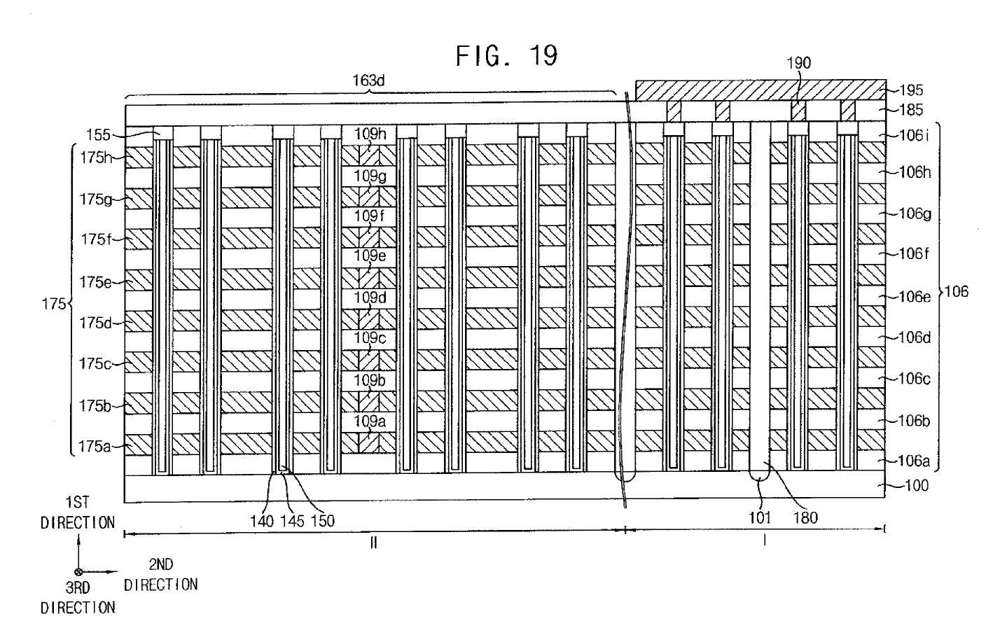

FIG. 19 is a cross-sectional view illustrating a vertical memory device in accordance with example embodiments. The vertical memory device of FIG. 19 may have constructions substantially the same as or similar to those illustrated with reference to FIG. 1 or 3 except for an addition of supporting patterns on a peripheral region. Thus, detailed descriptions on repeated elements and structures are omitted.

Referring to FIG. 19, a second cell block 163d disposed on a peripheral region II may include supporting patterns 109 (e.g., 109a to 109h) formed at a central portion thereof.

In example embodiments, the supporting pattern 109 may be disposed at each level including a gate line 175. The supporting pattern 109 may be sandwiched or interposed between a pair of the gate lines 175 at the each level. The supporting patterns 109 may be also sandwiched or interposed in the first direction by insulating interlayer patterns 106. In example embodiments, the supporting patterns 109 may be disposed between neighboring channel bundles, and may extend in the third direction. Accordingly, the gate line 175 formed at the each level of the second cell block 163d may be cut or blocked in-between by the supporting pattern 109.

The supporting pattern 109 may include a nitride-based material, e.g., silicon nitride or silicon boronitride. The supporting pattern 109 may be provided between the insulating interlayer patterns 106 to prevent a bending or a collapse thereof.

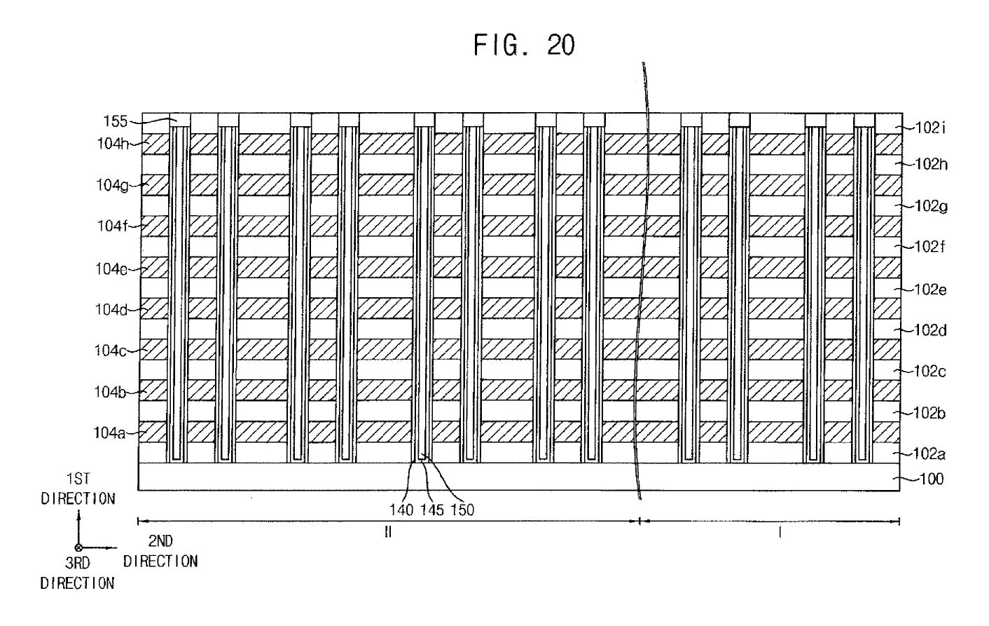

FIGS. 20 to 24 are cross-sectional views illustrating a method of manufacturing a vertical memory device in accordance with example embodiments. For example, FIGS. 20 to 24 illustrate a method of manufacturing the vertical memory device of FIG. 19. Detailed descriptions on processes and/or materials substantially the same as or similar to those illustrated with reference to FIGS. 5 to 19 are omitted.

Referring to FIG. 20, processes substantially the same as or similar to those illustrated with reference to FIGS. 5 to 12 may be performed. Accordingly, insulating interlayers 102 and sacrificial layers 104 may be formed alternately and repeatedly on a substrate 100 including a central region I and a peripheral region II. A dielectric layer structure 140, a channel 145 and a first filling layer pattern 150 may be formed through the insulating interlayers 102 and the sacrificial layers 104. A pad 155 may be formed on the dielectric layer structure 140, the channel 145 and the first filling layer pattern 150.

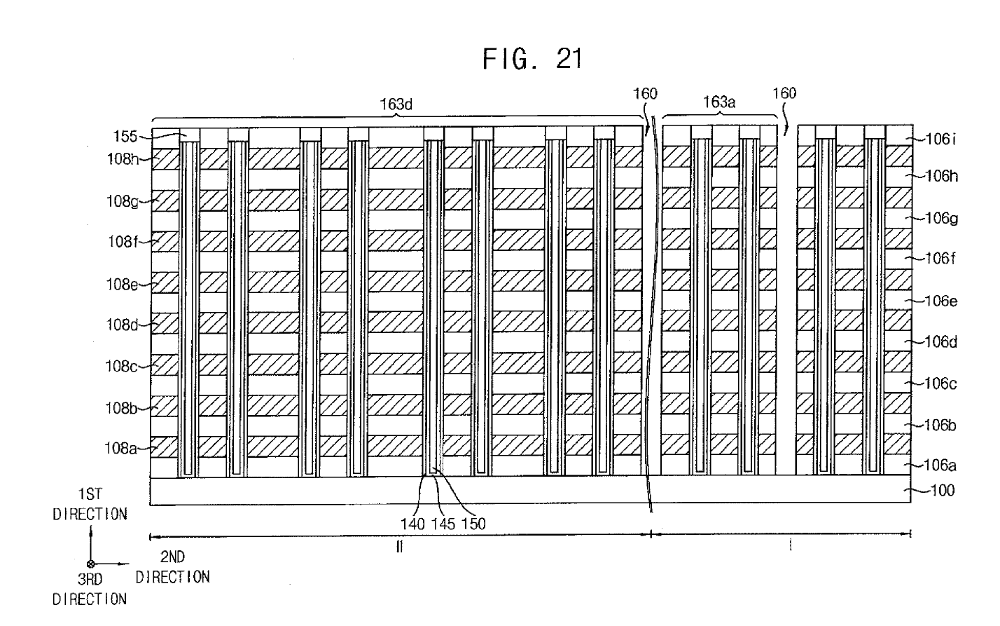

Referring to FIG. 21, a process substantially the same as or similar to that illustrated with reference to FIG. 13A or FIG. 13B. Accordingly, portions of the sacrificial layers 102 and the sacrificial layers 104 between neighboring channel bundles may be etched to form openings 160 extending in the third direction. The sacrificial layers 102 and the sacrificial layers 104 may be changed into insulating interlayer patterns 106 and sacrificial layer patterns 108, respectively, by the formation of the openings 160.

A first cell block 163a and a second cell block 163d may be also formed by the formation of the openings 160 on the central region I and the peripheral region II, respectively. FIG. 21 illustrates one second cell block 163d on the peripheral region II as illustrated in FIG. 13B. However, a plurality of the second cell blocks having a width greater than that of the first second cell block 163a may be formed on the peripheral region II.

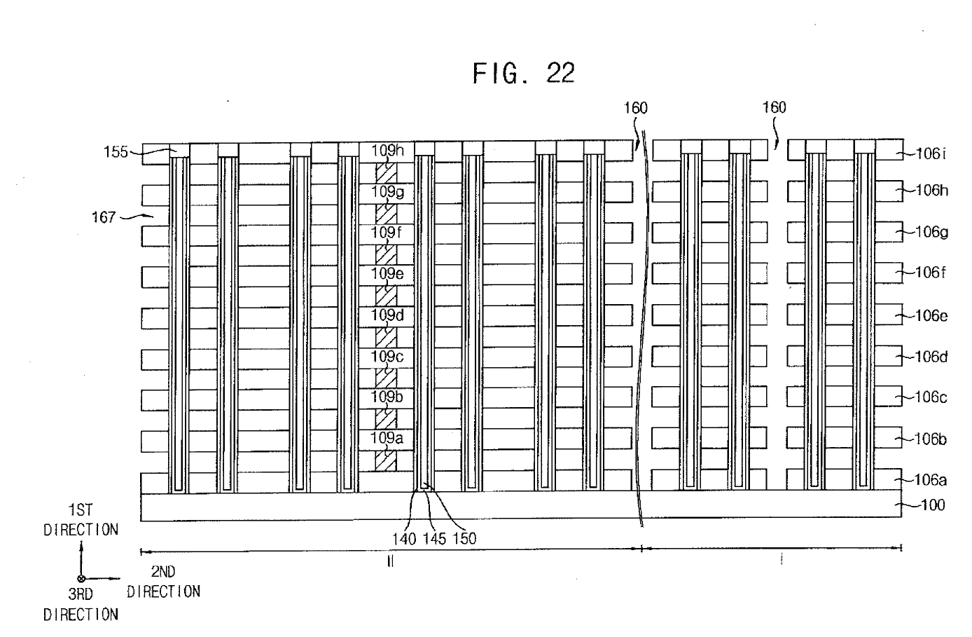

Referring to FIG. 22, a process substantially the same as or similar to that illustrated with reference to FIG. 14 may be performed to remove the sacrificial layer patterns 108 exposed by the openings 160.

The width of the second cell block 163d on the peripheral region II may be greater than the width of the first cell block 163a on the central region I, and thus a length of the sacrificial layer pattern 108 at each level of the peripheral region II may be relatively increased. Accordingly, when the sacrificial layer patterns 108 of the central regions I are removed, the sacrificial layer patterns 108 of the peripheral region II may be partially remained at a central portion of the second cell block 163d. For example, the supporting patterns 109 may be obtained by controlling an etching time for removing the sacrificial layer patterns 108.

As illustrated in FIG. 22, the remaining portions of the sacrificial layer patterns 108 may be changed into the supporting patterns 109 to support the insulating interlayer patterns 106 of the second cell block 163d. Thus, the insulating interlayer patterns 106 may be limited (and/or prevented) from being leaned or collapsed during subsequent processes.

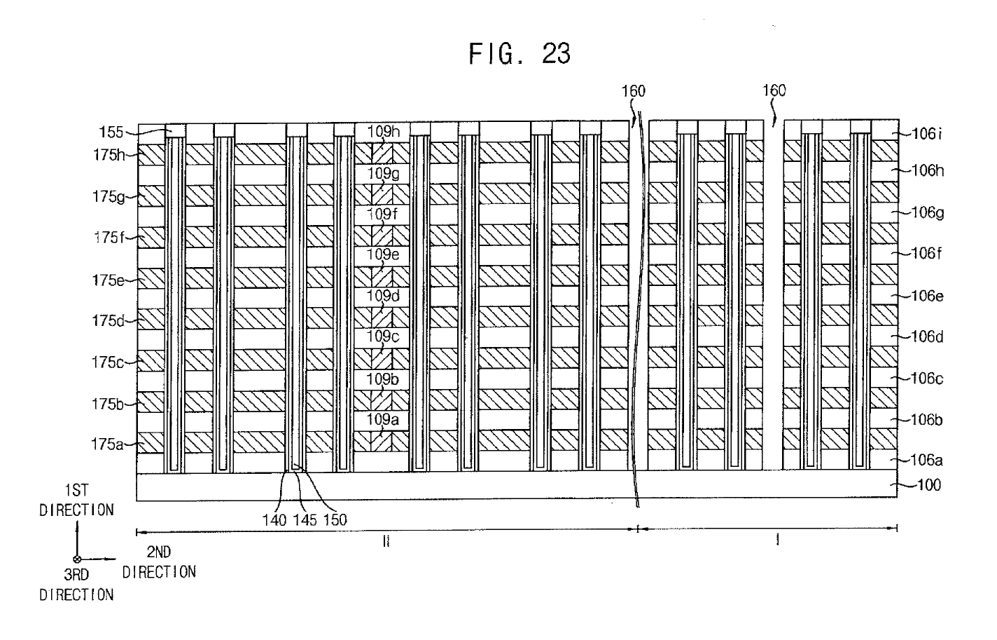

Referring to FIG. 23, processes substantially the same as or similar to those illustrated with reference to FIGS. 15 and 16 may be performed to form a gate line 175 at each level between the insulating interlayer patterns 106.

The supporting pattern 109 may be sandwiched or interposed between the gate lines 175 at the each level of the peripheral region II. Thus, the gate line 175 at the each level of the peripheral region II may be cut or blocked in-between by the supporting pattern 109.

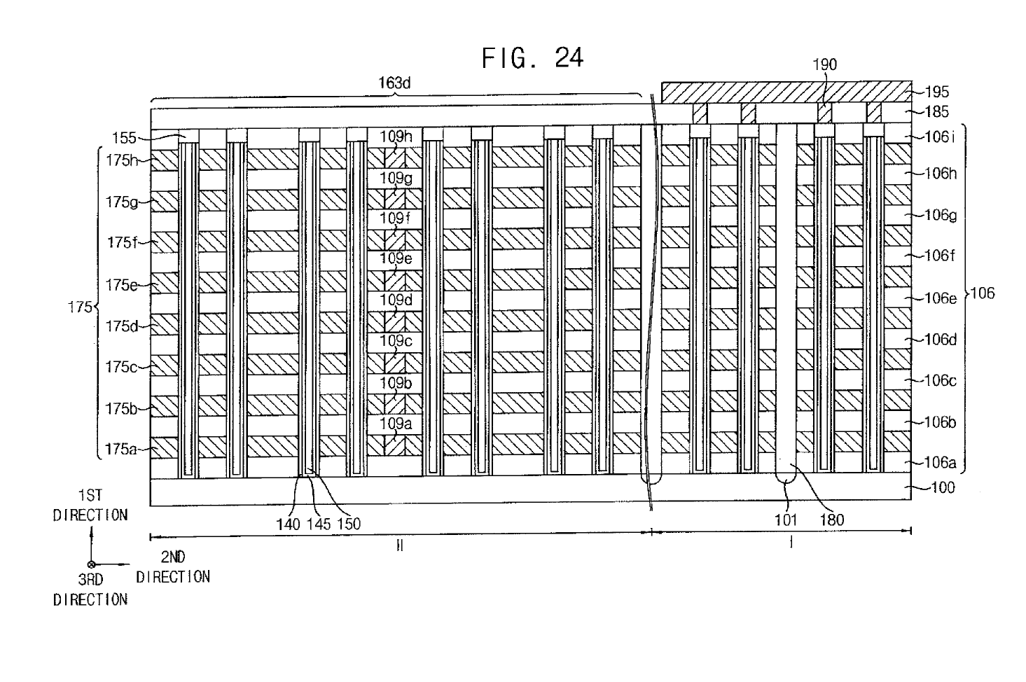

Referring to FIG. 24, processes substantially the same as or similar to those illustrated with reference to FIGS. 17 and 18 may be performed. Accordingly, an impurity region 101 may be formed at an upper portion of the substrate 100 exposed by the opening 160, and a second filling layer pattern 180 may be formed on the impurity region 101 to fill the opening 160. A bit line contact 190 may be formed through an upper insulation layer 185 to contact the pad 155. A bit line 195 may be formed on the upper insulation layer 185 to be electrically connected to the bit line contact 190. As illustrated in FIG. 18, the bit line contact 190 and the bit line 195 may be selectively arranged so that electrical or operational signals may be transferred to the channels 145, the pads 150 and/or the gate lines 175 formed on the central region I.

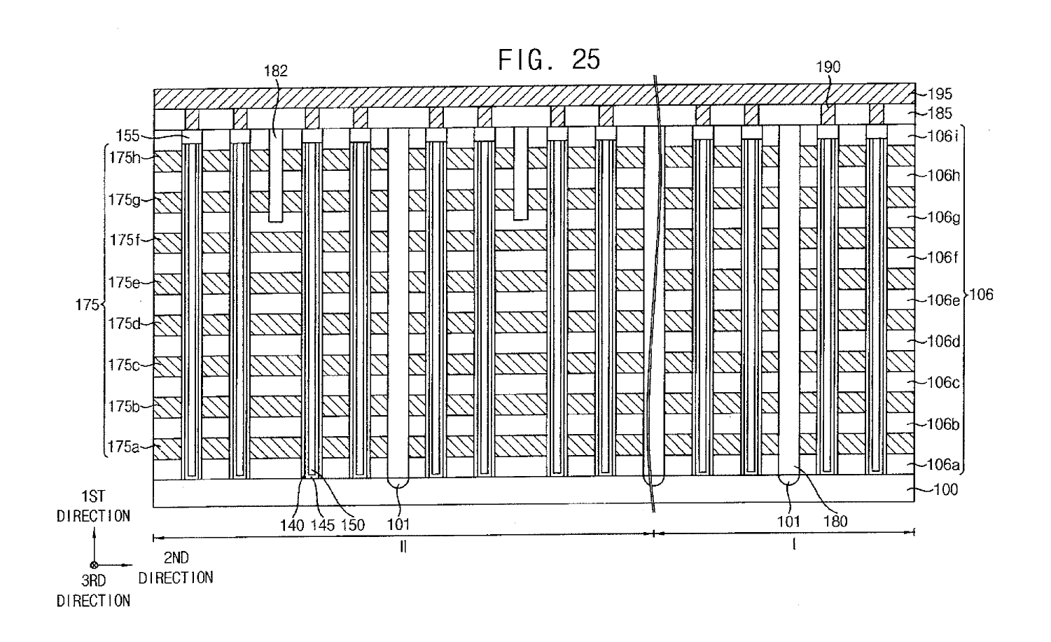

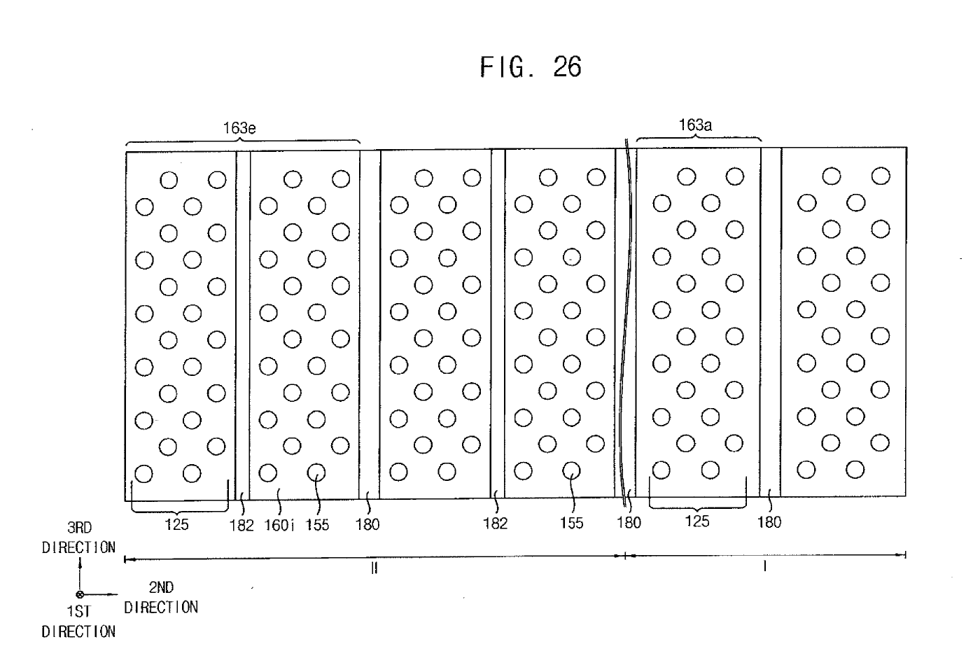

FIGS. 25 and 26 are a cross-sectional view and a top-plan view, respectively, illustrating a vertical memory device in accordance with example embodiments. For the convenience of explanation, an illustration of some elements of FIG. 25 including an upper insulation layer, a bit line and a bit line contact is omitted in FIG. 26.

The vertical memory device of FIGS. 25 and 26 may have constructions substantially the same as or similar to those illustrated with reference to FIGS. 1 and 2 except for a separation layer pattern. Thus, detailed descriptions on repeated elements and/or structures are omitted.

Referring to FIGS. 25 and 26, the vertical memory device may include a separation layer pattern 182 on a peripheral region II.

In example embodiments, the separation layer pattern 182 may extend through some insulating interlayer patterns 106 and gate lines 175 between channel bundles of a second cell block 163e on the peripheral region II. The separation layer pattern 182 may include an insulation material, e.g., silicon oxide.

The separation layer pattern 182 may serve as an SSL cut pattern of the second cell block 163e on the peripheral region II. In this case, the separation layer pattern 182 may extend through the gate lines 175h and 175g serving as the SSL, an uppermost insulating interlayer pattern 106i, the insulating interlayer pattern 106h between the SSLs, and an upper portion of the insulating interlayer pattern 106g directly under the SSL.

In example embodiments, the separation layer pattern 182 may cut the SSL of the second cell block 163e by a unit of a channel bundle 125 included in a first cell block 163a. For example, if the first cell block 163a includes 4 channel rows as illustrated in FIG. 26, the channel rows included in the second cell block 163e may be divided into 4 channel row-groups by the separation layer pattern 182.

The separation layer pattern 182 may be provided on the peripheral region II so that the second cell block 163e may have operational characteristics substantially the same or similar to those of the first cell block 163a. Even though the second cell block 163e has a width greater than that of the first cell block 163a and includes more channel bundles 125 than the first cell block 163e, the SSLs of the second cell block 163e may be divided by the separation layer pattern 182. Accordingly, memory cells of the second cell block 163e may participate in an operation of the vertical memory device. Bit line contacts 190 and bit lines 195 may be electrically connected to pads 155 and/or channels 145 formed on both central and peripheral regions I and II.

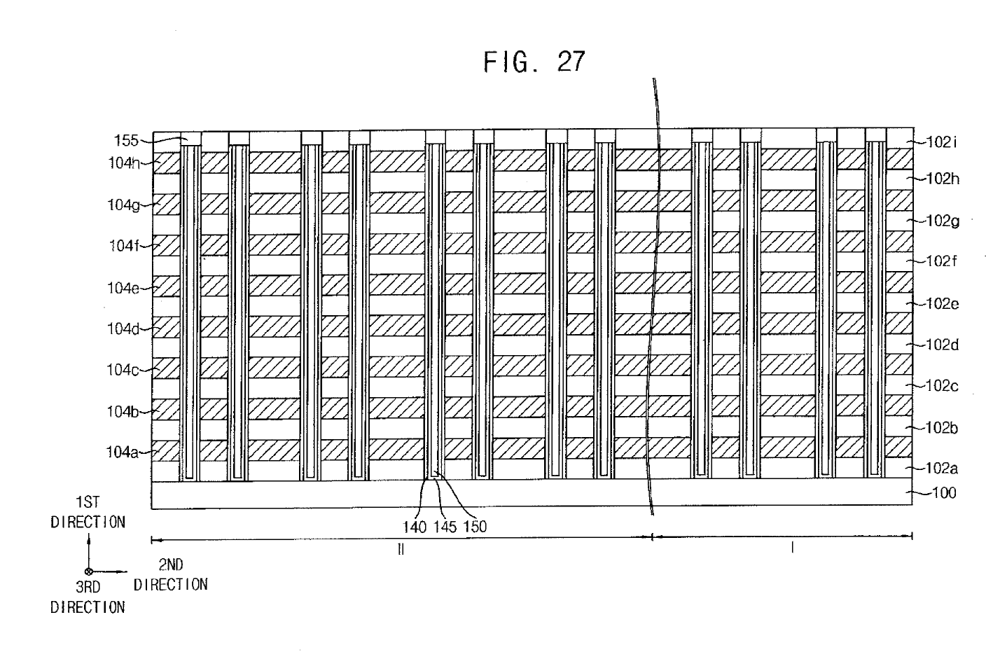

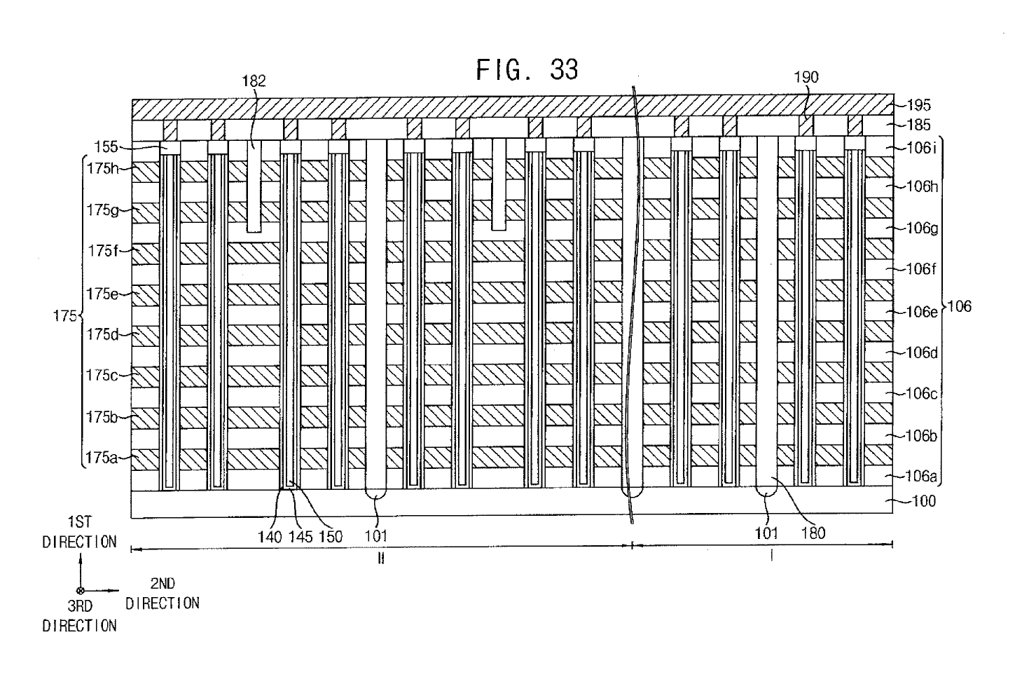

FIGS. 27 to 33 are cross-sectional views illustrating a method of manufacturing a vertical memory device in accordance with example embodiments. For example, FIGS. 27 to 33 illustrate a method of manufacturing the vertical memory device of FIGS. 25 and 26. Detailed descriptions on processes and/or materials substantially the same as or similar to those illustrated with reference to FIGS. 5 to 18 are omitted.

Referring to FIG. 27, processes substantially the same as or similar to those illustrated with reference to FIGS. 5 to 12 may be performed. Accordingly, insulating interlayers 102 and sacrificial layers 104 may be formed alternately and repeatedly on a substrate 100 including a central region I and a peripheral region II. A dielectric layer structure 140, a channel 145 and a first filling layer pattern 150 may be formed through the insulating interlayers 102 and the sacrificial layers 104. A pad 155 may be formed on the dielectric layer structure 140, the channel 145 and the first filling layer pattern 150.

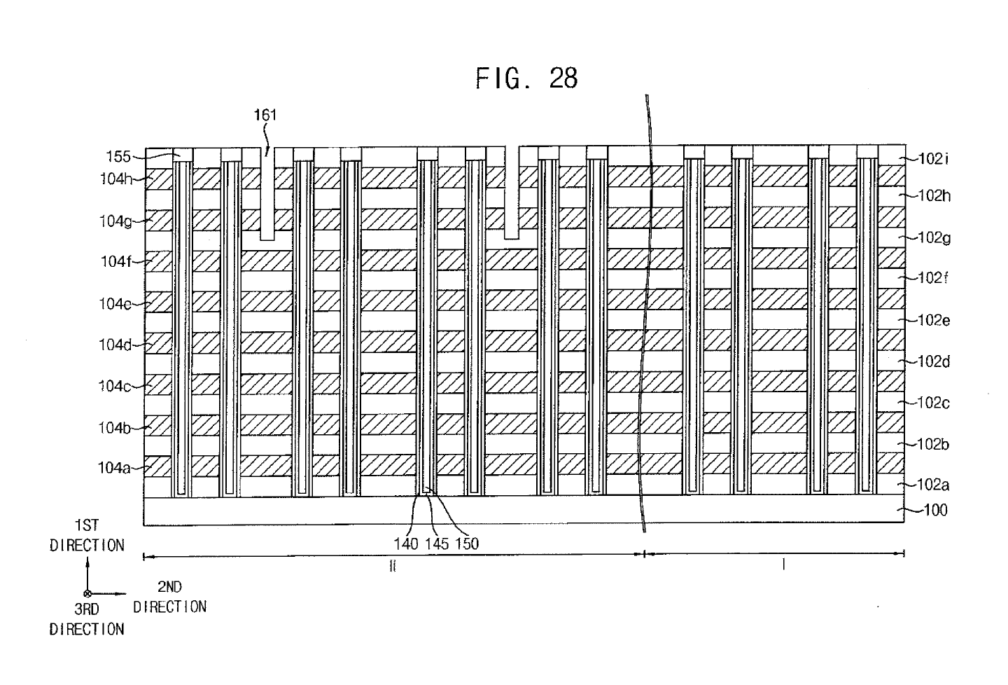

Referring to FIG. 28, portions of the insulating interlayers 102 and the sacrificial layers 104 formed on the peripheral region II may be partially etched to form a trench 161.

For example, a hard mask (not illustrated) exposing portions of an uppermost insulating interlayer 102i between neighboring channel bundles on the peripheral region II may be formed on the insulating interlayer 102i. The insulating interlayers 102 and the sacrificial layers 104 may be partially etched using the hard mask as an etching mask to form the trench 161.

In example embodiments, the trench 161 may serve as an SSL cut region of the peripheral region II. In this case, the trench 161 may be formed through the uppermost insulating interlayer 102i, the sacrificial layers 104h and 104g that may be replaced by the SSL, the insulating interlayer 102h between the sacrificial layers 104h and 104g, and an upper portion of the insulating interlayer 102g directly under the sacrificial layer 104g.

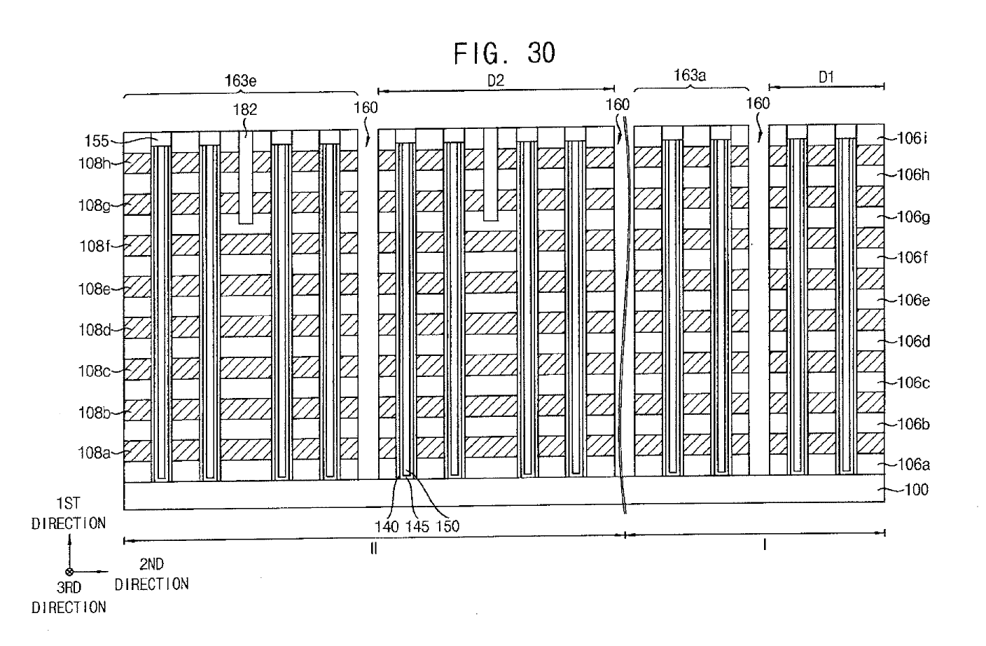

In example embodiments, the trench 161 may extend in the third direction and may divide the channel bundles included in a second cell block 163e (see FIG. 30) according to a unit of the channel bundle of a first cell block 163a (see FIG. 30). For example, if the second cell block 163e includes two channel bundles, one trench 161 may be formed for each second cell block 163e. If the second cell block 163e includes 3 or 4 channel bundles, 2 or 3 trenches 161 may be formed for each second cell block 163e.

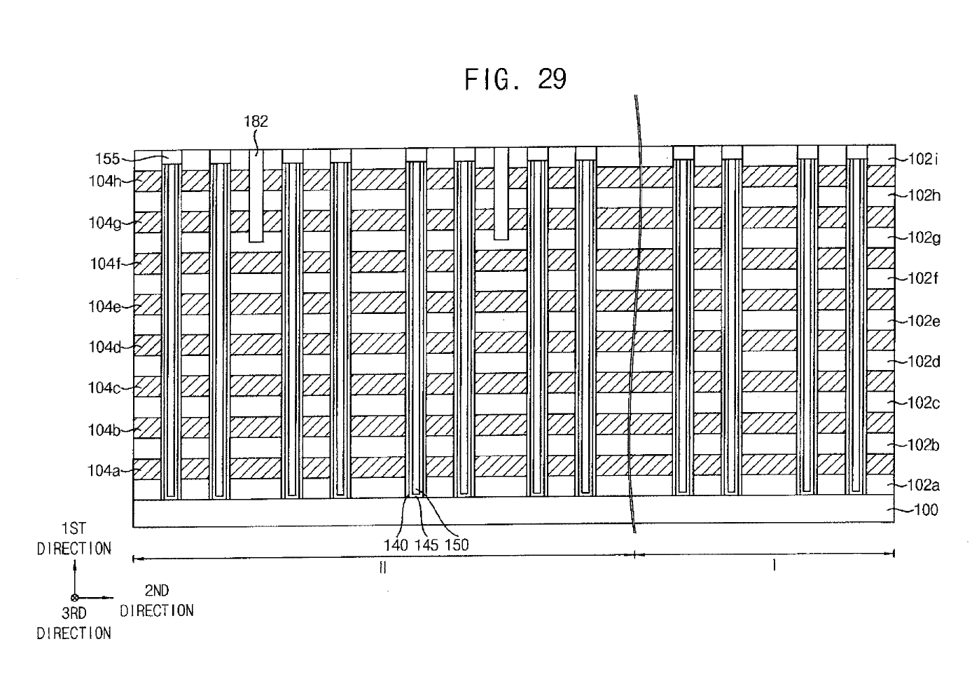

Referring to FIG. 29, a separation layer pattern 182 may be formed in the trench 161.

In example embodiments, a separation layer filling the trench 161 may be formed on the uppermost insulating interlayer 102i and the pads 155. An upper portion of the separation layer may be planarized by a CMP process and/or an etch-back process until the uppermost insulating interlayer 102i is exposed to form the separation layer pattern 182. The separation layer may be formed using silicon oxide by, e.g., a CVD process or a spin coating process.

Referring to FIG. 30, a process substantially the same as or similar to that illustrated with reference to FIG. 13A may be performed to form openings 160.

The sacrificial layers 102 and the sacrificial layers 104 may be changed into insulating interlayer patterns 106 and sacrificial layer patterns 108, respectively, by the formation of the openings 160.

A first cell block 163a and a second cell block 163e may be also formed by the by the formation of the openings 160 on the central region I and the peripheral region II, respectively. The first cell block 163a may have a first width D1 and the second cell block 163e may have a second width D2 greater than the first width D1. In example embodiments, the first cell block 163a may include one channel bundle, and the second cell block 163e may include at least two channel bundles.

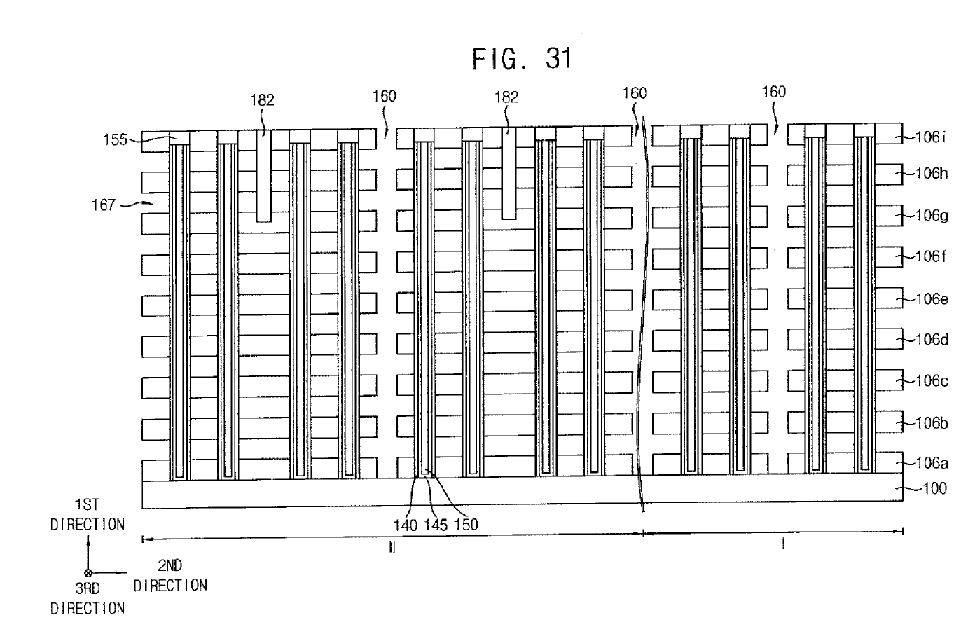

Referring to FIG. 31, a process substantially the same as or similar to that illustrated with reference to FIG. 14 may be performed to remove the sacrificial layer patterns 108, sidewalls of which are exposed by the openings 160.

Gaps 167 may be formed at spaces from which the sacrificial layer patterns 108 are removed. Sidewalls of the dielectric layer structure 140 and the separation layer pattern 182 may be partially exposed by the gaps 167.

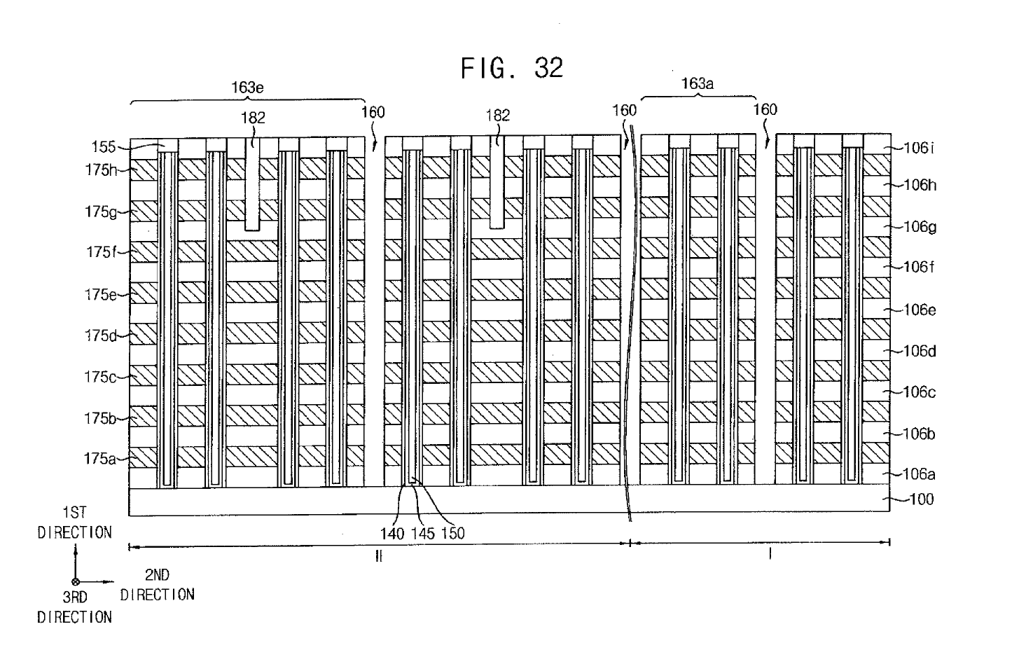

Referring to FIG. 32, processes substantially the same as or similar to those illustrated with reference to FIGS. 15 and 16 may be performed to form a gate line 175 at each level between the insulating interlayer patterns 106.

In example embodiments, the SSLs 175h and 175g included in the second cell block 163e of the peripheral region II may be separated by the separation layer pattern 182 between the neighboring channel bundles.

Referring to FIG. 32, processes substantially the same as or similar to those illustrated with reference to FIGS. 17 and 18 may be performed. Accordingly, an impurity region 101 may be formed at an upper portion of the substrate 100 exposed by the opening 160, and a second filling layer pattern 180 may be formed on the impurity region 101 to fill the opening 160. A bit line contact 190 may be formed through an upper insulation layer 185 to contact the pad 155. A bit line 195 may be formed on the upper insulation layer 185 to be electrically connected to the bit line contact 190. The bit line contact 190 and the bit line 195 may be electrically connected to pads 155 and/or channels 145 formed on both central and peripheral regions I and II.

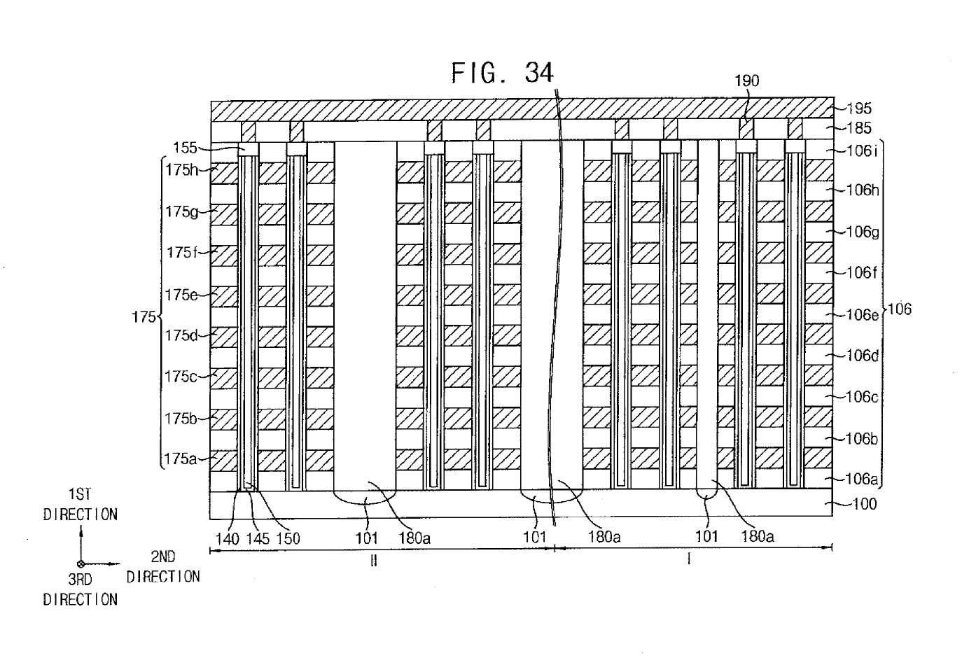

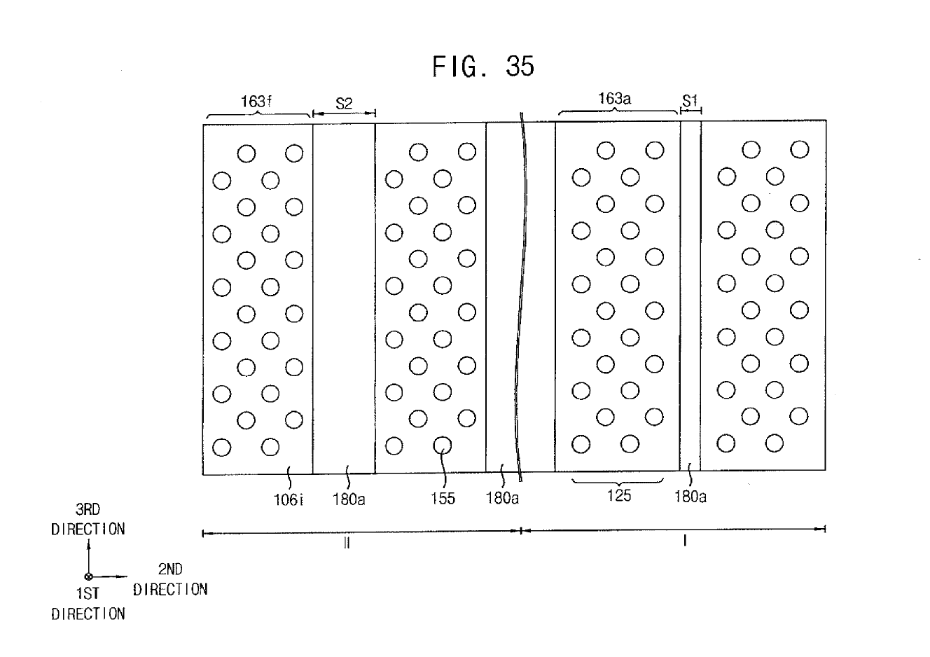

FIGS. 34 and 35 are a cross-sectional view and a top-plan view, respectively, illustrating a vertical memory device in accordance with example embodiments.

For the convenience of explanation, an illustration of some elements of FIG. 34 including an upper insulation layer, a bit line and a bit line contact is omitted in FIG. 35.

Detailed descriptions on elements and/or structures substantially the same as or similar to those illustrated with reference to FIGS. 1 and 2 are omitted.

Referring to FIGS. 34 and 35, a first cell block 163a and a second cell block 163f may be disposed on a central region I and a peripheral region II, respectively. FIGS. 34 and 35 illustrate two cell blocks on each of the central region I and the peripheral region II. However, the number of the cell blocks is not limited herein. The first and second cell blocks 163a and 163f may be defined by second filling layer patterns 180a. The first and second cell blocks 163a and 163f may have substantially the same width.

In example embodiments, a distance between the neighboring first cell blocks 163a on the central region I (denoted as a first distance “S1”) may be smaller than a distance between the neighboring second cell blocks 163f on the peripheral region II (denoted as a second distance “S2”). For example, the second cell block 163f may include the same number of a channel bundle 225 as that of the first cell block 163a. However, the second cell blocks 163f may be arranged on the peripheral region II with a pitch or a space larger than that of the first cell blocks 163a on the central region I.

Accordingly, a density of the cell blocks per a unit area of a substrate 100 may be reduced on the peripheral region II. Thus, a stress concentrated on the peripheral region II may be dispersed or reduced so that a bending, a leaning or a collapse of the second cell block 163f may be limited (and/or prevented). Further, even though the second cell blocks 163f are partially leaned on the peripheral region II, a collision therebetween may be avoided because the second cell blocks 163f are spaced apart from each other by a relatively large distance.

As illustrated in FIG. 34, The bit line contacts 190 and the bit line 195 may be electrically connected to pads 155 and/or channels 145 formed on both central and peripheral regions I and II. Alternatively, the bit line contacts 190 and the bit line 195 may be arranged to be electrically connected only to the pads 155 and/or the channels 145 disposed on the central region I. In this case, the peripheral region II may serve as a dummy region.

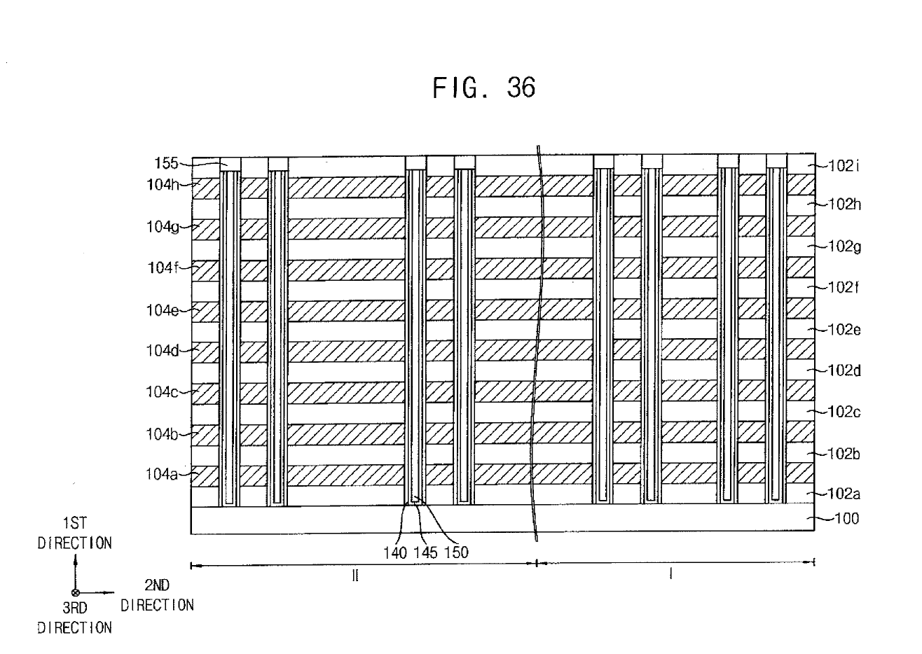

FIGS. 36 to 40 are cross-sectional views illustrating a method of manufacturing a vertical memory device in accordance with example embodiments. For example, FIGS. 36 to 40 illustrate a method of manufacturing the vertical memory device of FIGS. 34 and 35. Detailed descriptions on processes and/or materials substantially the same as or similar to those illustrated with reference to FIGS. 5 to 18 are omitted.

Referring to FIG. 36, processes substantially the same as or similar to those illustrated with reference to FIGS. 5 to 12 may be performed. Accordingly, insulating interlayers 102 and sacrificial layers 104 may be formed alternately and repeatedly on a substrate 100 including a central region I and a peripheral region II. A dielectric layer structure 140, a channel 145 and a first filling layer pattern 150 may be formed through the insulating interlayers 102 and the sacrificial layers 104. A pad 155 may be formed on the dielectric layer structure 140, the channel 145 and the first filling layer pattern 150.

In example embodiments, a density of the channel bundle 125 (see FIG. 35) of the peripheral region I may be lower than that of the central region I. For example, a distance between the channel bundles 125 of the peripheral region II may be greater than that of the central region I.

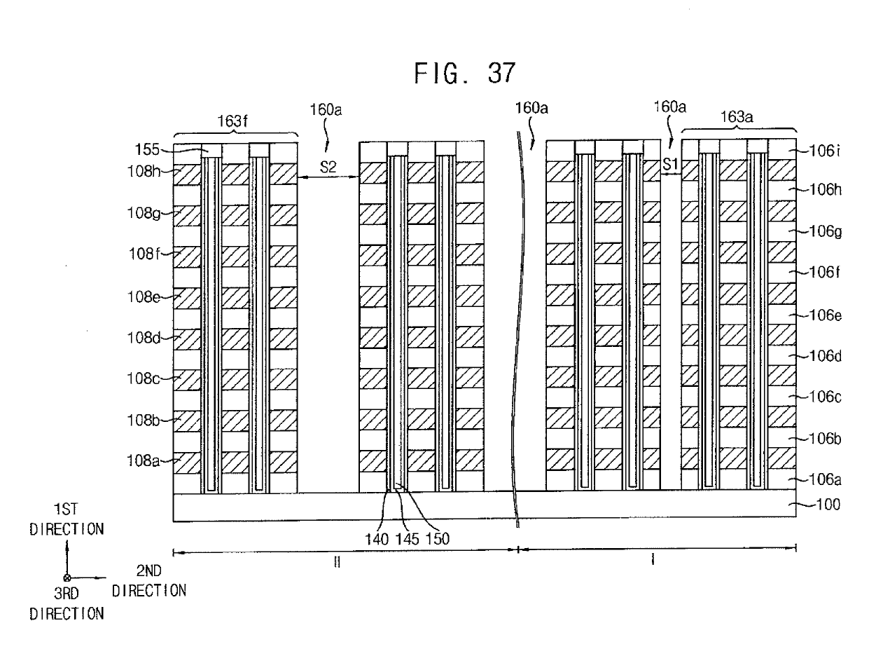

Referring to FIG. 37, a process substantially the same as or similar to that illustrated with reference to FIG. 13A may be performed to form openings 160a.

The sacrificial layers 102 and the sacrificial layers 104 may be changed into insulating interlayer patterns 106 and sacrificial layer patterns 108, respectively, by the formation of the openings 160a. A first cell block 163a and a second cell block 163f may be also formed by the formation of the openings 160 on the central region I and the peripheral region II, respectively.

In example embodiments, a width of the opening 160a formed on the peripheral region II may be greater than a width of the opening 160a formed on the central region I. For example, the opening 160a on the central region I may have a first width S1 and the opening 160a on the peripheral region II may have a second width S2 greater than the first width S1.

In example embodiments, the second cell block 163f may include the same number of the channel bundle 125 as that of the first cell block 163a. In this case, the second cell block 163f and the first cell block 163a may have substantially the same width.

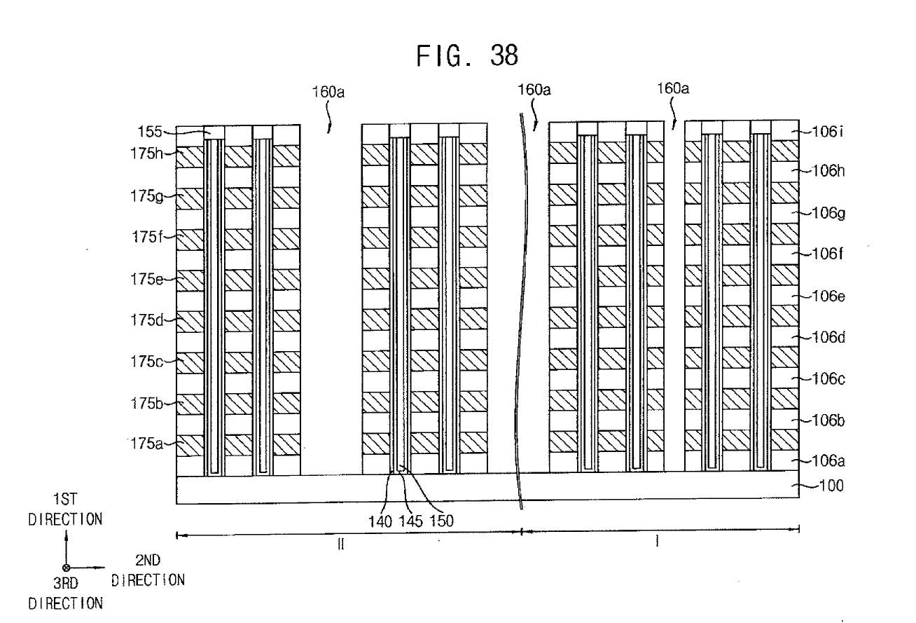

Referring to FIG. 38, processes substantially the same as or similar to those illustrated with reference to FIGS. 14 to 16 may be performed. Accordingly, the sacrificial layer patterns 108 may be replaced with gate lines 175.

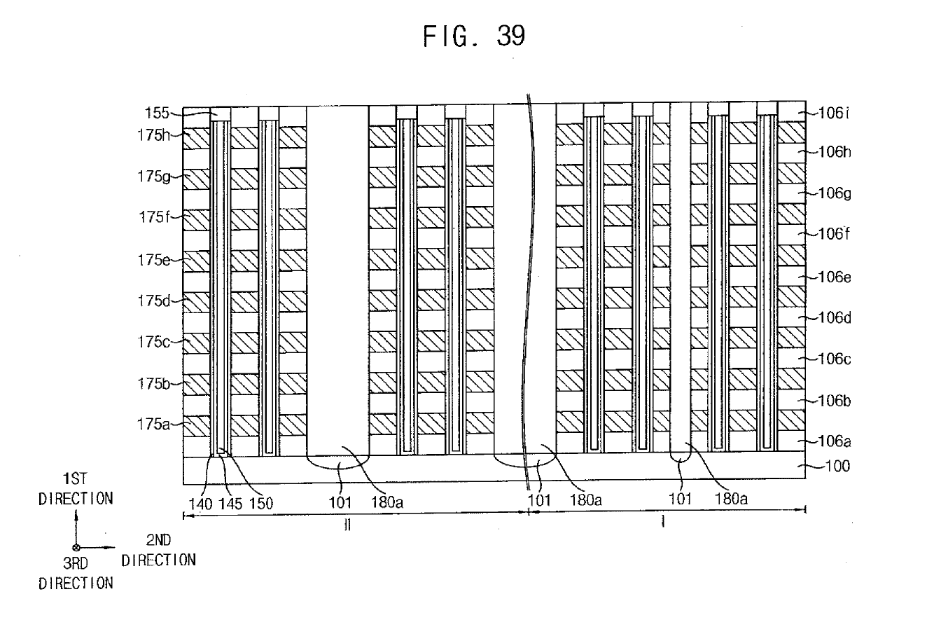

Referring to FIG. 39, a process substantially the same as or similar to that illustrated with reference to FIG. 17 may be performed. Accordingly, an impurity region 101 may be formed at an upper portion of the substrate 100 exposed by the opening 160a, and a second filling layer pattern 180a may be formed on the impurity region 101 to fill the opening 160a.

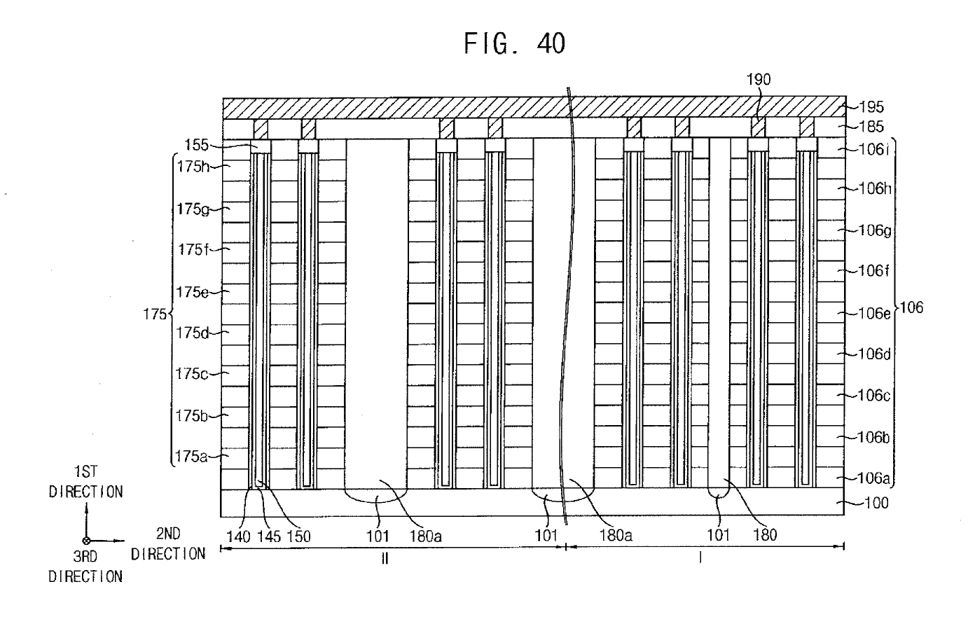

Referring to FIG. 40, a process substantially the same as or similar to that illustrated with reference to FIG. 18 may be performed. Accordingly, a bit line contact 190 may be formed through an upper insulation layer 185 to contact the pad 155. A bit line 195 may be formed on the upper insulation layer 185 to be electrically connected to the bit line contact 190.

In example embodiments, as illustrated in FIG. 40, the bit line 195 and the bit line contact 190 may be electrically connected to the pads 155 and/or the channels 145 formed on both central and peripheral regions I and II. In this case, the second cell block 163f of the peripheral region II may participate in an operation of the vertical memory device.

In example embodiments, as illustrated in FIG. 1, the bit line 195 and the bit line contact 190 may be electrically connected only to the pads 155 and/or the channels 145 formed on the central region I. In this case, the second cell block 163f of the peripheral region II may be provided as dummy cells.

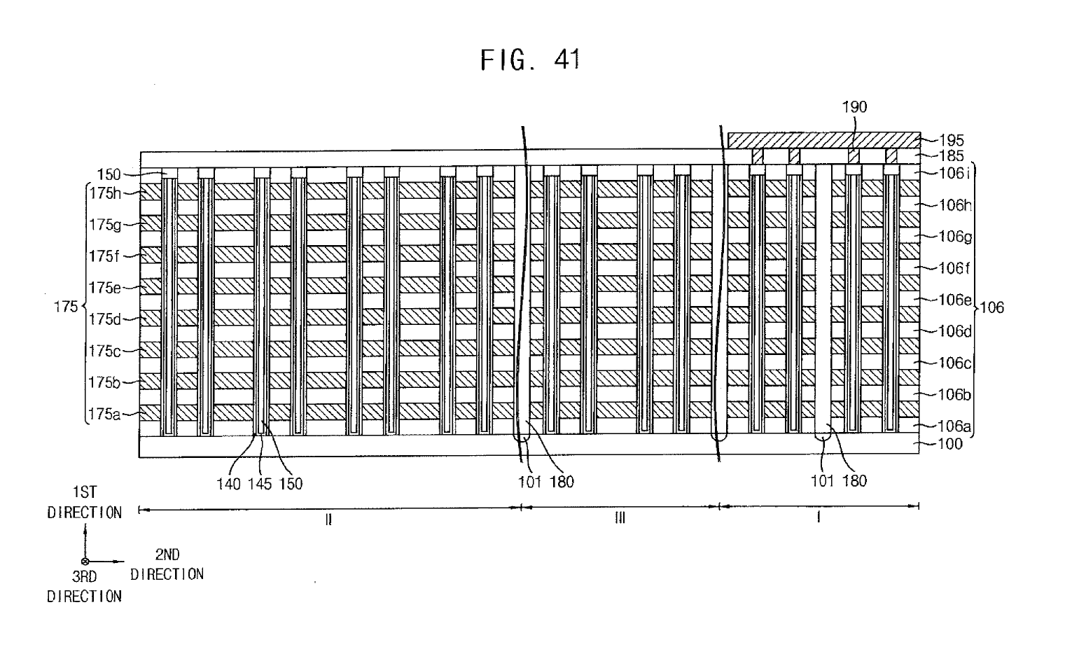

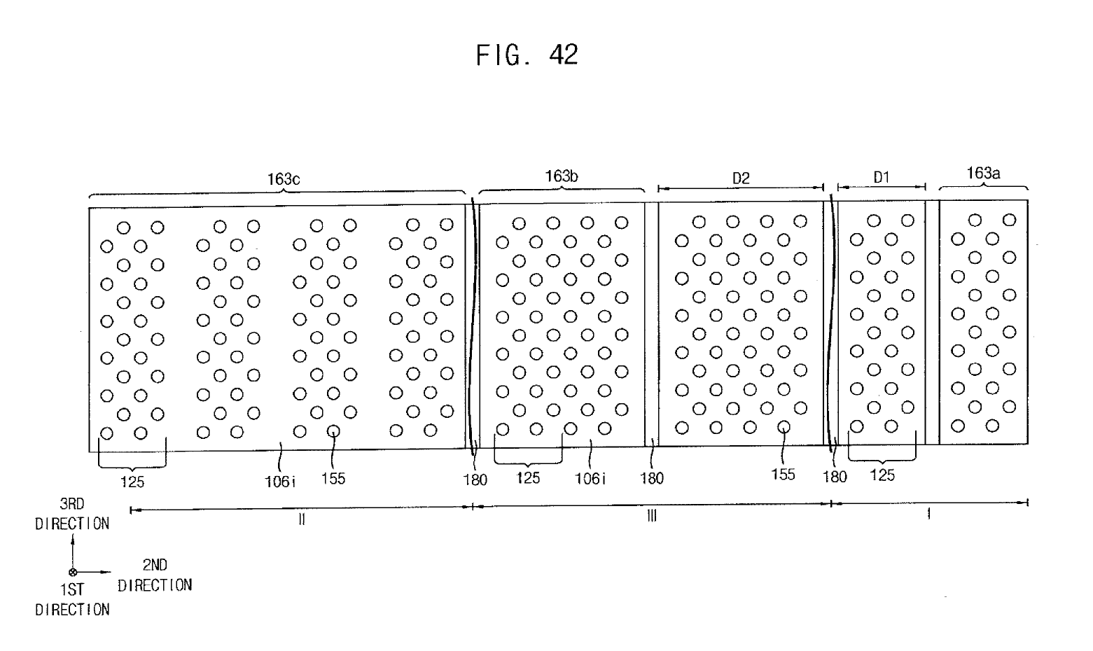

FIGS. 41 and 42 are a cross-sectional view and a top-plan view, respectively, illustrating a vertical memory device in accordance with example embodiments. Only the differences between the vertical memory devices in FIGS. 1-2, 3-4, and 41-42 will be described.

Referring to FIGS. 41-42, the substrate may include an intermediate region III between the central region I and the peripheral region II. At least one of the first cell blocks 163a may be on the central region I. At least one of the second cell blocks 163b described previously with reference to FIGS. 1-2 may be on the intermediate region III. At least one of the second cell blocks 163c described previously with reference to FIGS. 3-4 may be on the peripheral region II. The second filling layer patterns 180 may separate the first cell blocks 163a, second cell block 163b, and second cell block 163c from each other. Although FIGS. 41-42 illustrate one second cell block 163b on the intermediate region III, a plurality of second cell blocks 163b may be on the intermediate region III and separated from each other by the second filling layer patterns 180. Although FIGS. 41-42 illustrate one second cell block 163c on the peripheral region II, a plurality of second cell blocks 163c may be on the peripheral region II and separated from each other by the second filling layer patterns 180.

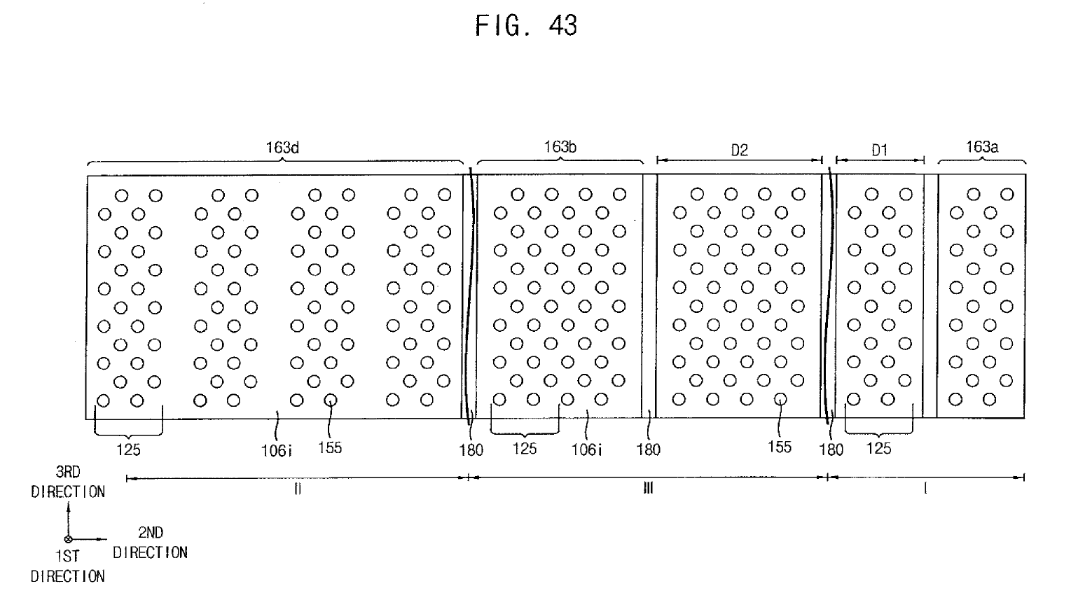

FIG. 43 is a top-plan view illustrating a vertical memory device in accordance with example embodiments. Only the difference between the vertical memory devices in FIGS. 1-2, 19, and 41-43 will be described.

Referring to FIG. 43, the substrate may include an intermediate region III between the central region I and the peripheral region II. At least one of the first cell blocks 163a may be on the central region I. At least one of the second cell blocks 163b described previously with reference to FIGS. 1-2 may be on the intermediate region III. At least one of the second cell blocks 163d described previously with reference to FIG. 19 may be on the peripheral region II. The second filling layer patterns 180 may separate the first cell blocks 163a, second cell block 163b, and second cell block 163d from each other. Although FIG. 43 illustrates one second cell block 163b on the intermediate region III, a plurality of second cell blocks 163b may be on the intermediate region III and separated from each other by the second filling layer patterns 180. Although FIG. 43 illustrate one second cell block 163d on the peripheral region II, a plurality of second cell blocks 163d may be on the peripheral region II and separated from each other by the second filling layer patterns 180.

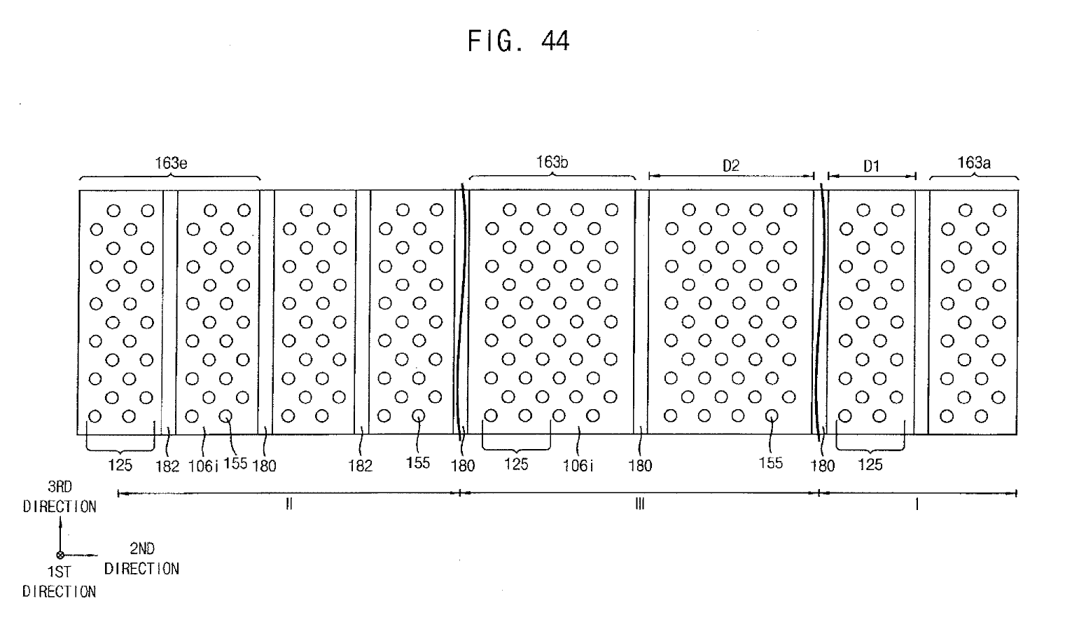

FIG. 44 is a top-plan view illustrating a vertical memory device in accordance with example embodiments. Only the difference between the vertical memory devices in FIGS. 1-2, 25-26, and 41-43 will be described.

Referring to FIG. 44, the substrate may include an intermediate region III between the central region I and the peripheral region II. At least one of the first cell blocks 163a may be on the central region I. At least one of the second cell blocks 163b described previously with reference to FIGS. 1-2 may be on the intermediate region III. At least one of the second cell blocks 163e described previously with reference to FIG. 25-26 may be on the peripheral region II. The second filling layer patterns 180 may separate the first cell blocks 163a, second cell block 163b, and second cell block 163e from each other. Although

FIG. 44 illustrates one second cell block 163b on the intermediate region III, a plurality of second cell blocks 163b may be on the intermediate region III and separated from each other by the second filling layer patterns 180. Although FIG. 44 illustrate one second cell block 163e on the peripheral region II, a plurality of second cell blocks 163e may be on the peripheral region II and separated from each other by the second filling layer patterns 180.

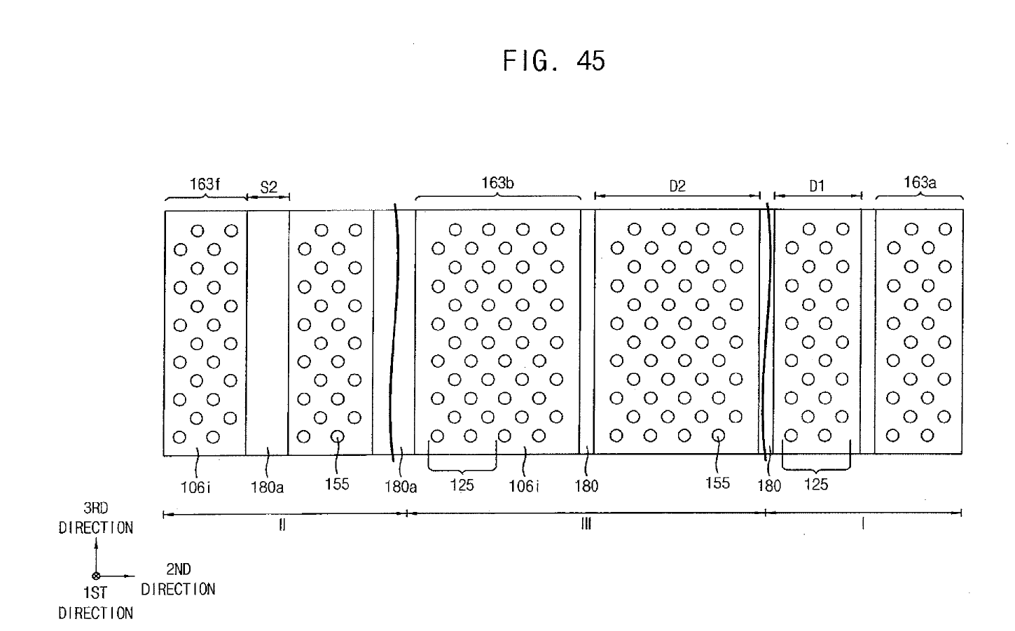

FIG. 45 is a top-plan view illustrating a vertical memory device in accordance with example embodiments. Only the difference between the vertical memory devices in FIGS. 1-2, 34-35, and 41-43 will be described.

Referring to FIG. 45, the substrate may include an intermediate region III between the central region I and the peripheral region II. At least one the first cell blocks 163a may be on the central region I. At least one of the second cell blocks 163b described previously with reference to FIGS. 1-2 may be on the intermediate region III. At least one of the second cell blocks 163f described previously with reference to FIG. 34-35 may be on the peripheral region II. The second filling layer patterns 180 may separate the first cell blocks 163a and second cell block 163b from each other. The second filling layer patterns 180a may separate the second cell block 163b from the second cell block 163f. Although FIG. 45 illustrates one second cell block 163b on the intermediate region III, a plurality of second cell blocks 163b may be on the intermediate region III and separated from each other by the second filling layer patterns 180. Although FIG. 45 illustrate one second cell block 163f on the peripheral region II, a plurality of second cell blocks 163f may be on the peripheral region II and separated from each other by the second filling layer patterns 180a.

According to example embodiments, a mold block or a cell block formed on peripheral or edge portions may have a width or a pitch greater than that of a mold block or a cell block formed on a cell region, so that the mold or cell blocks on the edge portion may be limited (and/or prevented) from being leaned, collapsed or bended. Therefore, the vertical memory device according to example embodiments may be implemented to a non-volatile memory device having a multi-stacked structure with a high aspect ratio.

The peripheral or edge portions may be utilized as a dummy region by a configuration of a bit line and/or a bit line contact as described above. However, even though the bit line and the bit line contact have a common configuration in both peripheral and cell regions, the peripheral portion may be utilized as the dummy region by a circuit design of a contact and a wiring.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

1. A vertical memory device, comprising:
a substrate including a central region and a peripheral region;
at least one first cell block on the central region, the first cell block including
a first channel extending in a first direction vertical to a top surface of the substrate, and
first gate lines surrounding the first channel and spaced apart from each other in the first direction; and
at least one second cell block on the peripheral region, the second cell block having a width greater than a width of the first cell block, the second block including
a second channel extending in the first direction vertical to the top surface of the substrate, and
second gate lines surrounding the second channel and spaced apart from each other in the first direction.

2. The vertical memory device of claim 1, wherein
the first cell block includes a plurality of first channels,
the plurality of first channels form a first channel bundle,
the second cell block includes a plurality of second channels, and
the plurality of second channels form a second channel bundle.

3. The vertical memory device of claim 2, wherein a number of the second channel bundles included in the second cell block is greater than a number of the first channel bundles included in the first cell block.

4. The vertical memory device of claim 3, wherein the first cell block includes one first channel bundle, and the second cell block includes at least two second channel bundles.

5. The vertical memory device of claim 3, wherein the second cell block further includes a separation layer pattern between the two of the at least two channel bundles, the two of the at least two channel bundles neighboring each other.

6. The vertical memory device of claim 5, wherein
the first gate lines of the first cell block include a first ground selection line (GSL), at least one first word line, and a first string selection line (SSL) sequentially stacked on each other from the top surface of the substrate,
the second gate lines of the second cell block include a second ground selection line (GSL), at least one second word line, and a second string selection line (SSL) sequentially stacked on each other from the top surface of the substrate, and
the separation layer pattern extends through the second SSL of the second cell block.

7. The vertical memory device of claim 1, wherein
the at least one first cell block is a plurality of first cell blocks on the central region, and
the at least one second cell block is one second cell block on the peripheral region.

8. The vertical memory device of claim 1, wherein the second cell block further includes a supporting pattern at a central portion of the second gate lines at each level of the second gate lines spaced apart from each other in the first direction.

9. The vertical memory device of claim 8, wherein
the first cell block further includes first insulating interlayer patterns stacked on each other between the first gate lines in the first direction,
the second cell block further includes second insulating interlayer patterns stacked on each other between the second gate lines in the first direction,
the first and second insulating interlayer patterns include silicon oxide, and
the supporting pattern includes silicon nitride.

10. The vertical memory device of claim 1, wherein further comprising:
filling layer patterns on the substrate, wherein
the at least one first cell block is a plurality of first cell blocks on the central region,
the at least one second cell block is one or a plurality of second cell blocks on the peripheral region, and
the filling layer patterns extend between at least one of the plurality of first cell blocks and the plurality of second cell blocks.

11. The vertical memory device of claim 10, wherein
the at least one second cell block is the plurality of second cell blocks,
the filling layer patterns extend between the plurality of first cell blocks and the plurality of second cell blocks,
a distance between the filling layer patterns on the peripheral region that neighbor each other is greater than a distance between the filling layer patterns on the central region that neighbor each other.

12. The vertical memory device of claim 10, wherein
the first cell block and the second cell block are spaced apart from each other in a second direction,
the first and second gate lines extend in a third direction,
the filling layer patterns extend in the third direction,
the second direction and third direction are parallel to the top surface of the substrate, and
the second direction and the third direction are perpendicular to each other.

13. The vertical memory device of claim 1, wherein the peripheral region is a dummy region.

14. The vertical memory device of claim 13, further comprising:
a bit line selectively and electrically connected to the first channel of the first cell block.

15. A vertical memory device, comprising:
a substrate including a central region and a peripheral region;
a plurality of first cell blocks on the central region, the first cell block including
a first channel extending in a first direction vertical to a top surface of the substrate, and
first gate lines surrounding the first channel and spaced apart from each other in the first direction;
a plurality of second cell blocks on the peripheral region, the second cell block including a second channel extending in the first direction vertical to the top surface of the substrate, and second gate lines surrounding the second channel and spaced apart from each other in the first direction, and a distance
between the plurality of second cell blocks that neighbor each other is greater than a distance between the plurality of first cell blocks that neighbor each other.

16. The vertical memory device of claim 15, wherein the plurality of first cell blocks and the plurality of second cell blocks have a same width.

17-25. (canceled)

26. A vertical memory device, comprising:
a substrate including a central region and a peripheral region; and
a stacked structure on the substrate,
the stacked structure including a plurality of channels extending in a first direction through a plurality of gate lines and a plurality of insulating layers alternately stacked on each other on the substrate,
the plurality of channels being spaced apart from each other,
the plurality of gate lines and insulating layers defining openings that expose the substrate and separate the stacked structure into a plurality of first cell blocks on the central region and at least one second cell block on the peripheral region of the substrate,
each one of the at least one second cell block having one of,
a width that is different than a width of any one of the plurality of first cell blocks, and
a different separation distance from an adjacent one of the plurality of first cell blocks compared to a separation distance between the plurality of first cell blocks that neighbor each other.

27. The vertical memory device of claim 26, wherein
each one of the at least one second cell block has the width that is different than the width of any one of the plurality of first cell blocks,
the width of each one of the at least one second cell block is greater than the width of any one of the plurality of first cell blocks, and
a number of the channels per each one of the at least one second cell block is greater than a number of the channels per any one of the plurality of first cell blocks.

28. The vertical memory device of claim 26, further comprising:
at least one bit line electrically connected to the plurality of channels in the plurality of first cell blocks that are below the bit line,
wherein the stacked structure includes a plurality of dielectric structures,
each one of the plurality of dielectric structures surrounds a corresponding one of the plurality of channels, and
the plurality of dielectric structures extend the first direction through the plurality of gate lines and insulating layers.

29. The vertically memory device of claim 26, wherein
the at least one second cell block is a plurality of second cell blocks on the peripheral region of the substrate,
a separation distance between the plurality of second cell blocks that neighbor each other is greater than the separation distance between the plurality of first cell blocks that neighbor each other, and
the openings that separate the stacked structure into the plurality of second blocks have a greater width than the openings that separate the stacked structure into the plurality of first blocks.
